(19) United States
(12) Patent Application Publication
(10) Pub. No.: US 2025/0254920 A1
(43) Pub. Date: Aug. 7, 2025

(54) NANOSTRUCTURE DEVICE WITH REDUCED HIGH-K DIELECTRIC AREA AND RELATED METHOD

(71) Applicant: Taiwan Semiconductor Manufacturing Co., Ltd., Hsinchu (TW)

(72) Inventors: Mao-Lin HUANG, Hsinchu (TW); Lung-Kun CHU, Hsinchu (TW); Chung-Wei HSU, Hsinchu (TW); Jia-Ni YU, Hsinchu (TW); Kuo-Cheng CHIANG, Hsinchu (TW); Chih-Hao WANG, Hsinchu (TW)

(21) Appl. No.: 18/656,149

(22) Filed: May 6, 2024

Related U.S. Application Data
(60) Provisional application No. 63/548,647, filed on Feb. 1, 2024.

(51) Int. Cl. H01L 29/423; H01L 29/06; H01L 29/66; H01L 29/775

(52) U.S. Cl. CPC H10D 30/6735; H10D 30/014; H10D 30/43; H10D 62/121; H10D 64/017; H10D 64/018; H10D 30/6736

(57) ABSTRACT

A method and device are provided, wherein the method includes forming a stack including nanostructure channels, interposers, and a hard mask structure by forming a source/drain opening. The method further includes forming a sacrificial gate structure on the stack, and forming a spacer layer adjacent the sacrificial gate structure. The method further includes releasing the nanostructure channels by removing the interposers, and forming a gate dielectric on the nanostructure channels and a side surface of the spacer layer. The method also includes forming a reduced gate dielectric by removing a portion of the gate dielectric from the side surface of the spacer layer, the portion being laterally adjacent to the nanostructure channels, and forming a gate metal layer on the reduced gate dielectric and exposed portions of the spacer layer.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A and 1B are diagrammatic cross-sectional side views of a portion of an IC device according to embodiments of the present disclosure.

FIGS. 2A-17 are views of various embodiments of an IC device of at various stages of fabrication according to various aspects of the present disclosure.

FIG. 18 is a flowchart of a method of forming an IC device in accordance with various embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Terms indicative of relative degree, such as “about,” “substantially,” and the like, should be interpreted as one having ordinary skill in the art would in view of current technological norms.

The terms “first,” “second,” “third” and so on may be used herein to describe a sequence of events or sequential order of elements but may be exchanged or varied in some contexts. For example, a second layer may be formed on (e.g., sequentially after) a first layer, but in some contexts the first layer may be referred to as a “second layer,” “third layer,” “fourth layer” or the like, and the second layer may be referred to as a “first layer,” “third layer,” “fourth layer,” or the like.

The term “surrounds” may be used herein to describe a structure that fully or partially encloses another element or structure, for example, in three dimensions. For example, a first structure may “surround” a second structure on four lateral sides (e.g., left, right, front and back) without surrounding the second structure on two vertical sides (e.g., top and bottom). In other example, the first structure may wrap partially around the second structure, for example, by wrapping around three sides (e.g., top, front and back) while leaving other sides (e.g., left, right and bottom) exposed.

Source/drain region(s) may refer to a source or a drain, individually or collectively dependent upon the context.

The present disclosure is generally related to semiconductor devices, and more particularly to field-effect transistors (FETs), such as planar FETs, three-dimensional fin FETs (FinFETs), or nanostructure FETs, such as nanosheet FETs (NSFETs), nanowire FETs (NWFETs), gate-all-around FETs (GAAFETs) and the like.

Nanostructure device performance improvement is challenging for nanosheet FETs under complicated device architectures and extreme scaling rules. For example, gate-to-drain capacitance (Cgd) reduction can improve device speed as well as power efficiency. Inclusion of sidewall spacers that have low dielectric materials is beneficial for reducing capacitance (Ceff) and boosting device performance. However, a gate last process in which an active replacement gate is formed following formation of the sidewall spacers can introduce significant increases in Cgd. For example, a high-k gate dielectric layer that is beneficially formed on active semiconductor channels is also formed covering the entire sidewall spacer.

In embodiments of the disclosure, the high-k gate dielectric layer is selectively removed from the sidewall spacer to reduce Cgd, while keeping the high-k gate dielectric layer inner spacers to reduce or eliminate gate leakage and reliability degradation. Cell dimension shrinking can be improved by top gate length enlargement due to removal of the high-k gate dielectric layer from the sidewall spacer. Gate resistance Rg can be reduced due to increased volume for gate metal gap fill.

The nanostructure transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the nanostructure structure.

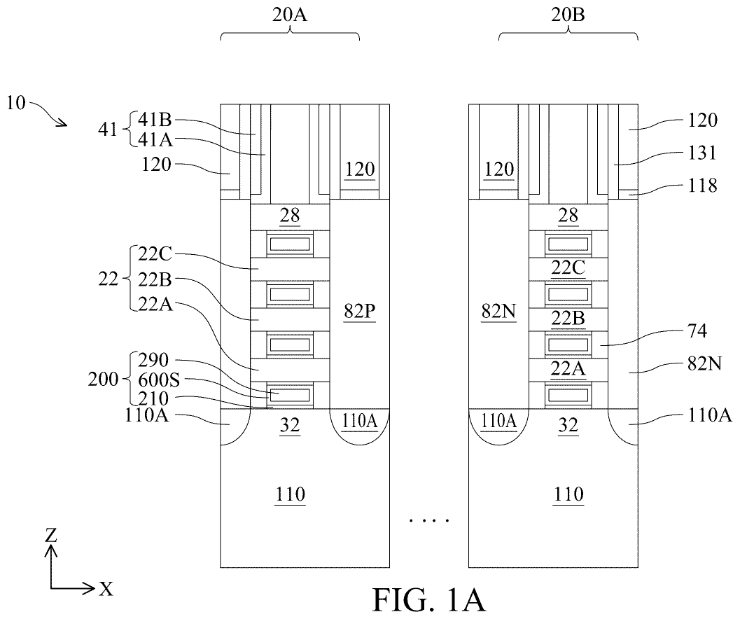

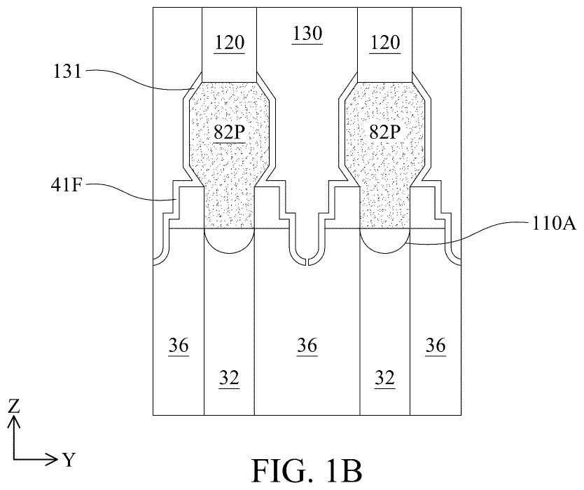

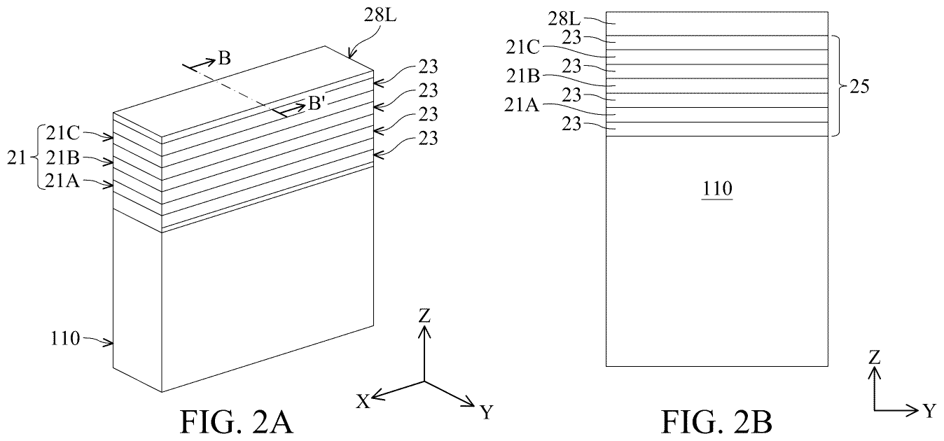

FIGS. 1A and 1B are diagrammatic cross-sectional side views of a portion of a nanostructure device 10 in accordance with various embodiments. FIG. 1A illustrates a view in an X-Z plane. FIG. 1B illustrates a view in a Y-Z plane orthogonal to the X-Z plane. The nanostructure device 10 of FIGS. 1A, 1B is described in detail below to provide context for understanding the technical features and benefits of the various embodiments depicted in FIGS. 2A-18.

Referring to FIG. 1A, nanostructure devices 20A, 20B may be or include one or more N-type FETs (NFETs) or P-type FETs (PFETs). For example, the nanostructure device 20A may be a PFET and the nanostructure device 20B may be an NFET. The nanostructure devices 20A, 20B are formed over and/or in a substrate 110, and generally include gate structures 200 straddling and/or wrapping around semiconductor channels 22A, 22B, 22C, alternately referred to as “nanostructures,” located over semiconductor fins 32 protruding from, and separated by, isolation structures 36 (see FIG. 1B). The semiconductor channels 22A, 22B, 22C may be referred to collectively as channels 22. The gate structure 200 controls electrical current flow through the channels 22A, 22B, 22C.

The nanostructure devices 20A, 20B are shown including three channels 22A, 22B, 22C, which are laterally abutted by source/drain features 82N, 82P, and covered and surrounded by the gate structure 200. Generally, the number of channels 22 is two or more, such as three or four or more, but can be one in some embodiments. The gate structure 200 controls flow of electrical current through the channels 22A, 22B, 22C to and from the source/drain features 82N, 82P based on voltages applied at the gate structure 200 and at the source/drain features 82N, 82P.

In some embodiments, the fin structure 32 includes silicon. In some embodiments, the nanostructure device 20B includes an NFET, and the source/drain features 82N thereof include silicon phosphorous (SiP), SiAs, SiSb, SiPAs, SiP:As:Sb, SiGe, combinations thereof, or the like. In some embodiments, the nanostructure device 20A includes a PFET, and the source/drain features 82P thereof include silicon germanium (SiGe), either undoped or doped to form, for example, SiGe:B, SiGe:B:Ga, SiGe:Sn, SiGe:B:Sn, or another appropriate semiconductor material. Generally, the source/drain features 82N, 82P may include any combination of appropriate semiconductor material(s) and appropriate dopant(s).

The channels 22A, 22B, 22C each include a semiconductive material, for example silicon or a silicon compound, such as silicon germanium, or the like. In some embodiments, the channels 22 are or include one or more of a semiconductor or semiconductor alloy, such as Si, SiGe, Ge, GaAs, InGaAs, SiGeSn, GeSn, one or more two-dimensional materials with semiconducting properties, such as MoS₂, WS₂, combinations thereof, and the like. The channels 22A, 22B, 22C are nanostructures (e.g., having at least one dimension that is in a range of a few nanometers) and may also each have an elongated shape and extend in the X-direction. In some embodiments, the channels 22A, 22B, 22C each have a nanowire (NW) shape, a nanosheet (NS) shape, a nanotube (NT) shape, or other suitable nanoscale shape. The cross-sectional profile of the channels 22A, 22B, 22C may be rectangular, round, square, circular, elliptical, hexagonal, or combinations thereof.

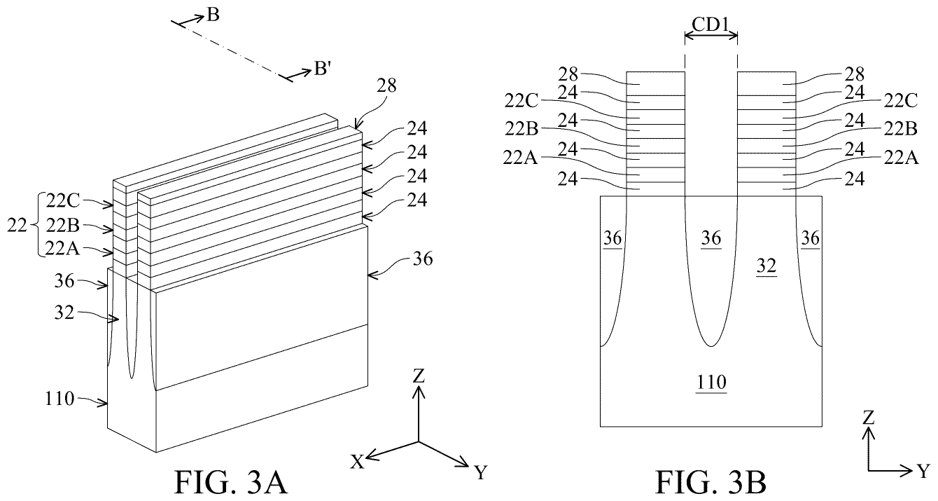

In some embodiments, the lengths (e.g., measured in the X-direction) of the channels 22A, 22B, 22C may be different from each other, for example due to tapering during a fin etching process (see FIGS. 3A, 3B). In some embodiments, length of the channel 22C may be less than a length of the channel 22B, which may be less than a length of channel 22A. The channels 22A, 22B, 22C each may not have uniform thickness (e.g., along the X-axis direction), for example due to a channel trimming process used to expand spacing (e.g., measured in the Z-axis direction) between the channels 22A, 22B, 22C to increase gate structure fabrication process window. For example, a middle portion of each of the channels 22A, 22B, 22C may be thinner than the two ends of each of the channels 22A, 22B, 22C. Such shape may be collectively referred to as a “dog-bone” shape.

In some embodiments, the spacing between the channels 22A, 22B, 22C (e.g., between the channel 22B and the channel 22A or the channel 22C) is in a range between about 1 nanometers (nm) and about 15 nm, such as between about 5.5 nm and about 10 nm, though ranges exceeding or below the said ranges may also be beneficial. In some embodiments, a thickness (e.g., measured in the Z-direction) of each of the channels 22A, 22B, 22C is in a range between about 1 nm and about 10 nm, though ranges exceeding or below the said range may also be beneficial. In some embodiments, a width (e.g., measured in the Y-direction, shown in FIG. 3B, orthogonal to the X-Z plane) of each of the channels 22A, 22B, 22C is at least about 8 nm, however the width may be less than 8 nm in some embodiments.

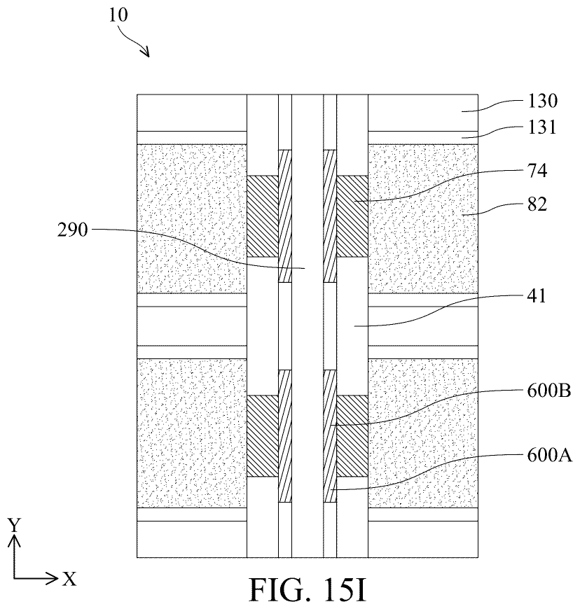

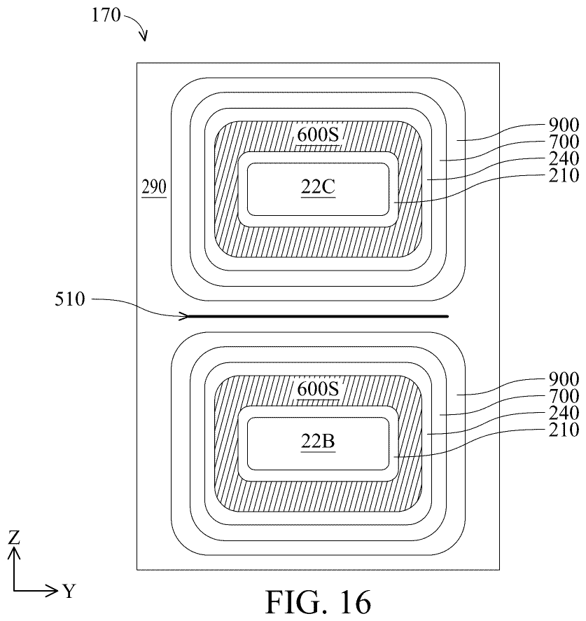

The gate structure 200 is disposed over and between the channels 22A, 22B, 22C, respectively. In some embodiments, the gate structure 200 is disposed over and between the channels 22A, 22B, 22C, which are silicon channels for N-type devices or silicon germanium channels for P-type devices. In some embodiments, the gate structure 200 includes an interfacial layer (IL) 210, one or more gate dielectric layers 600 on the interfacial layer 210 and a metal core layer 290 on the gate dielectric layer 600. Additional layers, such as one or more work function tuning layers 900 (see FIG. 16) may be present on the gate dielectric layer 600 between the gate dielectric layer 600 and the metal core layer 290.

The interfacial layer 210, which may be an oxide of the material of the channels 22A, 22B, 22C, is formed on exposed areas of the channels 22A, 22B, 22C and the top surface of the fin 32. The interfacial layer 210 promotes adhesion of the gate dielectric layers 600 to the channels 22A, 22B, 22C. In some embodiments, the interfacial layer 210 has thickness of about 5 Angstroms (A) to about 50 Angstroms (A). In some embodiments, the interfacial layer 210 has thickness of about 10 A. The interfacial layer 210 having thickness that is too thin may exhibit voids or insufficient adhesion properties. The interfacial layer 210 being too thick consumes gate fill window, which is related to threshold voltage tuning and resistance. In some embodiments, the interfacial layer 210 is doped with a dipole, such as lanthanum, for threshold voltage tuning.

In some embodiments, the gate dielectric layer 600 includes at least one high-k gate dielectric material, which may refer to dielectric materials having a high dielectric constant that is greater than a dielectric constant of silicon oxide (k˜3.9). Example high-k dielectric materials include HfO₂, HfSiO, HfSiON, HfTaO, HfTiO, HfZrO, ZrO₂, Ta₂O₅, or combinations thereof. In some embodiments, the gate dielectric layer 600 has thickness of about 5 A to about 100 A. The gate dielectric layer 600 may be a single layer or a multilayer.

In embodiments of the disclosure, the gate dielectric layer 600 can be a reduced high-k dielectric layer 600S that covers only a portion of a gate spacer 41, as will be described with reference to FIGS. 2A-18. Reduction of area of the gate dielectric layer 600 that covers the gate spacer 41 can reduce effective capacitance and boost speed of the device 10.

The gate structure 200 also includes metal core layer 290. The metal core layer 290 may include a conductive material such as Co, W, Ru, combinations thereof, or the like. In some embodiments, the metal core layer 290 is or includes a Co-, W- or Ru-based compound or alloy including one or more elements, such as Zr, Sn, Ag, Cu, Au, Al, Ca, Be, Mg, Rh, Na, Ir, W, Mo, Zn, Ni, K, Co, Cd, Ru, In, Os, Si, Ge, Mn, combinations thereof, or the like. Between the channels 22A, 22B, 22C, in the X-Z plane, the metal core layer 290 is circumferentially surrounded (in the cross-sectional view) by the one or more work function metal layers 900, which are then circumferentially surrounded by the gate dielectric layers 600, which are circumferentially or partially surrounded by the interfacial layer 210.

As depicted in FIG. 1A, the nanostructure devices 20A, 20B may further include source/drain contacts 120 that are formed over the source/drain features 82N, 82P. The source/drain contacts 120 may include a core layer that is or includes a conductive material such as tungsten, ruthenium, cobalt, copper, titanium, titanium nitride, tantalum, tantalum nitride, iridium, molybdenum, nickel, aluminum, or combinations thereof. The core layer may be surrounded by one or more liner (or, “barrier”) layers, such as SiN or TiN, which help prevent or reduce diffusion of materials from and into the source/drain contacts 120. In some embodiments, height of the source/drain contacts 120 may be in a range of about 1 nm to about 50 nm.

Silicide layers 118 may be positioned between the source/drain features 82N, 82P and the source/drain contacts 120, at least to reduce the source/drain contact resistance. In some embodiments, the silicide layer 118 is or includes TiSi, CrSi, TaSi, MoSi, ZrSi, HfSi, ScSi, Ysi, HoSi, TbSl, GdSi, LuSi, DySi, ErSi, YbSi, or the like. In some embodiments, the silicide layer 118 is or includes NiSi, CoSi, MnSi, Wsi, FeSi, RhSi, PdSi, RuSi, PtSi, IrSi, OsSi, or the like. The silicide layer 118 may have thickness in a range of about 1 nm to about 10 nm. Thickness lower than about 1 nm may lead to an insufficient reduction in contact resistance. Thickness above about 10 nm may cause electrical shorting with the nanostructures 22. In some embodiments, the silicide layer 118 is present below, and in contact with, etch stop layer 131.

As depicted in FIG. 1B, the nanostructure devices 20A, 20B may further include an interlayer dielectric (ILD) 130. The ILD 130 provides electrical isolation between the various components of the nanostructure devices 20A, 20B discussed above, for example between neighboring pairs of the source/drain contacts 120. An etch stop layer (ESL) 131 may be formed prior to forming the ILD 130 and may be positioned laterally between the ILD 130 and the gate spacers 41 and vertically between the ILD 130 and the source/drain features 82N, 82P. In some embodiments, the etch stop layer 131 is or includes SiN, SiCN, SiC, SiOC, SiOCN, HfO₂, ZrO₂, ZrAlOₓ, HfAlOₓ, HfSiOₓ, Al₂O₃, or other suitable material. In some embodiments, thickness of the etch stop layer 131 is in a range of about 1 nm to about 5 nm. In some embodiments, where the ILD 130 is not present (e.g., is removed completely prior to formation of the source/drain contacts 120), the etch stop layer 131 may be in contact with the source/drain contact 120. The etch stop layer 131 may be trimmed, for example, in the X-axis direction prior to formation of the source/drain contact 120 to improve fill quality of the source/drain contact 120.

The nanostructure devices 20A, 20B include gate spacers 41 that are disposed on sidewalls of the metal core layer 290 above the channel 22C, and inner spacers 74 that are disposed on sidewalls of the IL 210 and/or the gate dielectric layer 600 between the channels 22A, 22B, 22C. The inner spacers 74 are also disposed between the channels 22A, 22B, 22C. In the embodiment depicted in FIG. 1A, the gate spacers 41 include a first spacer layer 41A and a second spacer layer 41B on the first spacer layer 41A. The first and second spacer layers 41A, 41B may each include a dielectric material, for example a low-k material such as SiOCN, SiON, SiN, SiCN, SiOC or the like. In some embodiments, the second spacer layer 41B is not present. Material of the first and second spacer layers 41A, 41B may be the same as or different from each other. In some embodiments, an upper portion of the second spacer layer 41B (or the first spacer layer 41A when the second spacer layer 41B is not present) may be removed partially or fully to increase aspect ratio of an opening through which the source/drain region 82N, 82P is formed. FIG. 1A depicts an embodiment in which the upper portion of the second spacer layer 41B is not thinned.

In embodiments of the disclosure, side surfaces of the gate spacers 41 may be substantially free of the high-k dielectric layer 600. For example, instead of being completely or mostly covered by the high-k dielectric layer 600, the side surfaces of the gate spacers 41 may have a percentage of their surface area covered by the high-k dielectric layer 600. The percentage may be in a range of about 2% to about 20%. Methods of reducing area of the high-k dielectric layer 600 covering the side surfaces of the gate spacers 41 in accordance with various embodiments are described with reference to FIGS. 2A-18.

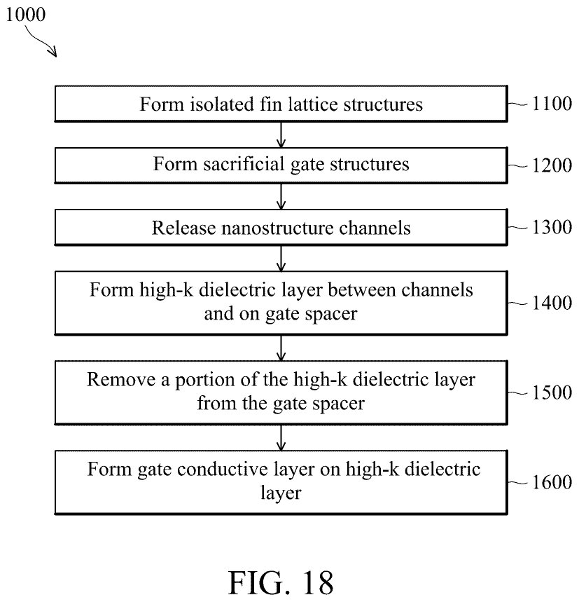

FIG. 18 depicts a flowchart of a method 1000 for forming an IC device or a portion thereof from a workpiece, according to one or more aspects of the present disclosure. Method 1000 is merely an example and not intended to limit the present disclosure to what is explicitly illustrated in method 1000. Additional acts can be provided before, during and after the method 1000 and some acts described can be replaced, eliminated, or moved around for additional embodiments of the method. Not all acts are described herein in detail for reasons of simplicity. Method 1000 is described below in conjunction with fragmentary perspective and/or cross-sectional views of a workpiece, shown in FIGS. 2A-17, at different stages of fabrication according to embodiments of method 1000. For avoidance of doubt, throughout the figures, the X direction is perpendicular to the Y direction and the Z direction is perpendicular to both the X direction and the Y direction. It is noted that, because the workpiece may be fabricated into a semiconductor device, the workpiece may be referred to as the semiconductor device as the context requires.

FIGS. 2A through 17 are views of intermediate stages in the manufacturing of FETs, such as nanostructure FETs, in accordance with some embodiments.

In FIG. 2A and FIG. 2B, a substrate 110 is provided. The substrate 110 may be a semiconductor substrate, such as a bulk semiconductor, or the like, which may be doped (e.g., with a p-type or an n-type dopant) or undoped. The semiconductor material of the substrate 110 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof. Other substrates, such as single-layer, multi-layered, or gradient substrates may be used.

Further in FIG. 2A and FIG. 2B, a multi-layer stack 25 or “lattice” is formed over the substrate 110 of alternating layers of first semiconductor layers 21A, 21B (collectively referred to as first semiconductor layers 21) and second semiconductor layers 23. In some embodiments, the first semiconductor layers 21 may be formed of a first semiconductor material, such as Si, SiGe, Ge, GaAs, InGaAs, GeSn, SiGeSn, Mos, WS₂, and the like, and the second semiconductor layers 23 may be formed of a second semiconductor material, such as SiGe, Ge, Si, InGaAs, AlGaAs, GeSn, SiGeSn or the like. Each of the layers 21, 23 of the multi-layer stack 25 may be epitaxially grown using a process such as chemical vapor deposition (CVD), atomic layer deposition (ALD), vapor phase epitaxy (VPE), molecular beam epitaxy (MBE), or the like. Each of the layers 21, 23 of the multi-layer stack 25 may be formed to have thickness in a range of about 1 nm to about 10 nm.

Three layers of the first semiconductor layers 21 and four layers of the second semiconductor layers 23 are illustrated. In some embodiments, the multi-layer stack 25 may include fewer or additional numbers of the first semiconductor layers 21 and the second semiconductor layers 23. Although the multi-layer stack 25 is illustrated as including a second semiconductor layer 23 as the bottommost layer and the topmost layer, in some embodiments, the bottommost layer and/or the topmost layer of the multi-layer stack 25 may be a first semiconductor layer 21.

Due to high etch selectivity between the first semiconductor materials and the second semiconductor materials, the second semiconductor layers 23 of the second semiconductor material may be removed without significantly removing the first semiconductor layers 21 of the first semiconductor material, thereby allowing the first semiconductor layers 21 to be patterned to form channel regions of nano-FETs. In some embodiments, the first semiconductor layers 21 are removed and the second semiconductor layers 23 are patterned to form channel regions. The high etch selectivity allows the first semiconductor layers 21 of the first semiconductor material to be removed without significantly removing the second semiconductor layers 23 of the second semiconductor material, thereby allowing the second semiconductor layers 23 to be patterned to form channel regions of nano-FETs.

In FIGS. 2A and 2B, a hard mask layer 28L is formed. The hard mask layer 28L may be a dielectric layer that includes one or more dielectric materials, such as SiO₂, Si₃N₄, SiON, SiCN, SiCON or the like. The hard mask layer 28L may be formed on the uppermost second semiconductor layer 23 via a suitable deposition process, such as a chemical vapor deposition (CVD), including low pressure chemical vapor deposition (LPCVD), plasma enhanced chemical vapor deposition (PECVD) or the like. The hard mask layer 28L may be or include one or more layers of SiO, SiN, SiON, SiCN, SiOCN or the like that are formed to a thickness that is in a range of about 1 nanometer (nm) to about 10 nm.

In FIG. 3A and FIG. 3B, fins 32 are formed in the substrate 110 and nanostructures 22, 24 are formed in the multi-layer stack 25 while hard mask structures 28 are also formed, corresponding to act 1100 of FIG. 18. In some embodiments, the nanostructures 22, 24 and the fins 32 may be formed by etching trenches in the multi-layer stack 25, the hard mask layer 28L and the substrate 110. The etching may be any acceptable etch process, such as a reactive ion etch (RIE), neutral beam etch (NBE), the like, or a combination thereof. The etching may be anisotropic. First nanostructures 22A, 22B, 22C (also referred to as “channels 22” below) are formed from the first semiconductor layers 21, second nanostructures 24 are formed from the second semiconductor layers 23 and the hard mask structures 28 are formed from the hard mask layer 28L. Distance CD1 between adjacent fins 32 and nanostructures 22, 24 may be from about 18 nm to about 100 nm, though distances less than or greater than the said range may also be beneficial and are embodiments herein. A portion of the device 10 is illustrated in FIGS. 3A and 3B including two fins 32 for simplicity of illustration. The process 1000 illustrated in FIG. 18 may be extended to any number of fins and is not limited to the two fins 32 shown in FIGS. 3A-17.

The fins 32 and the nanostructures 22, 24 may be patterned by any suitable method. For example, one or more photolithography processes, including double-patterning or multi-patterning processes, may be used to form the fins 32 and the nanostructures 22, 24. Generally, double-patterning or multi-patterning processes combine photolithography and self-aligned processes, allowing for pitches smaller than what is otherwise obtainable using a single, direct photolithography process. As an example of one multi-patterning process, a sacrificial layer may be formed over a substrate and patterned using a photolithography process. Spacers are formed alongside the patterned sacrificial layer using a self-aligned process. The sacrificial layer is then removed, and the remaining spacers may then be used to pattern the fins 32.

FIGS. 3A and 3B illustrate the fins 32 having tapered sidewalls, such that a width of each of the fins 32 and/or the nanostructures 22, 24 continuously increases in a direction towards the substrate 110. In such embodiments, each of the nanostructures 22, 24 may have a different width and be trapezoidal in shape. In other embodiments, the sidewalls are substantially vertical (non-tapered), such that width of the fins 32 and the nanostructures 22, 24 is substantially similar, and each of the nanostructures 22, 24 is rectangular in shape.

In FIGS. 3A and 3B, isolation regions, features or structures 36, which may be shallow trench isolation (STI) regions, features or structures, are formed adjacent the fins 32. The isolation regions 36 may be formed by depositing an insulation material over the substrate 110, the fins 32, the nanostructures 22, 24 and the hard mask structures 28, and between adjacent fins 32, nanostructures 22, 24 and hard mask structures 28. The insulation material may be an oxide, such as silicon oxide, a nitride, the like, or a combination thereof, and may be formed by high-density plasma CVD (HDP-CVD), flowable CVD (FCVD), the like, or a combination thereof. In some embodiments, a liner (not separately illustrated) may first be formed along surfaces of the substrate 110, the fins 32, the nanostructures 22, 24 and the hard mask structures 28. Thereafter, a core material, such as those discussed above may be formed over the liner.

The insulation material undergoes a removal process, such as a chemical mechanical polish (CMP), an etch-back process, combinations thereof, or the like, to remove excess insulation material over the nanostructures 22, 24 and the hard mask structures 28. Top surfaces of the hard mask structures 28 may be exposed and level with the insulation material after the removal process is complete.

The insulation material is then recessed to form the isolation regions 36. After recessing, the nanostructures 22, 24, the hard mask structures 28 and upper portions of the fins 32 may protrude from between neighboring isolation regions 36. The isolation regions 36 may have top surfaces that are flat as illustrated, convex, concave, or a combination thereof. In some embodiments, the isolation regions 36 are recessed by an acceptable etching process, such as an oxide removal using, for example, dilute hydrofluoric acid (dHF), which is selective to the insulation material and leaves the fins 32, the hard mask structures 28 and the nanostructures 22, 24 substantially unaltered.

FIGS. 2A through 3B illustrate one embodiment (e.g., etch last) of forming the fins 32, the hard mask structures 28 and the nanostructures 22, 24. In some embodiments, the fins 32, the hard mask structures 28 and/or the nanostructures 22, 24 are epitaxially grown or deposited in trenches in a dielectric layer (e.g., etch first). The epitaxial structures may comprise the alternating semiconductor materials discussed above, such as the first semiconductor materials and the second semiconductor materials.

In FIG. 3A and FIG. 3B, appropriate wells (not separately illustrated) may be formed in the fins 32, the nanostructures 22, 24, and/or the isolation regions 36. Using masks, an n-type impurity implant may be performed in p-type regions of the substrate 110, and a p-type impurity implant may be performed in n-type regions of the substrate 110. Example n-type impurities may include phosphorus, arsenic, antimony, or the like. Example p-type impurities may include boron, boron fluoride, indium, or the like. An anneal may be performed after the implants to repair implant damage and to activate the p-type and/or n-type impurities. In some embodiments, in situ doping during epitaxial growth of the fins 32 and the nanostructures 22, 24 may obviate separate implantations, although in situ and implantation doping may be used together.

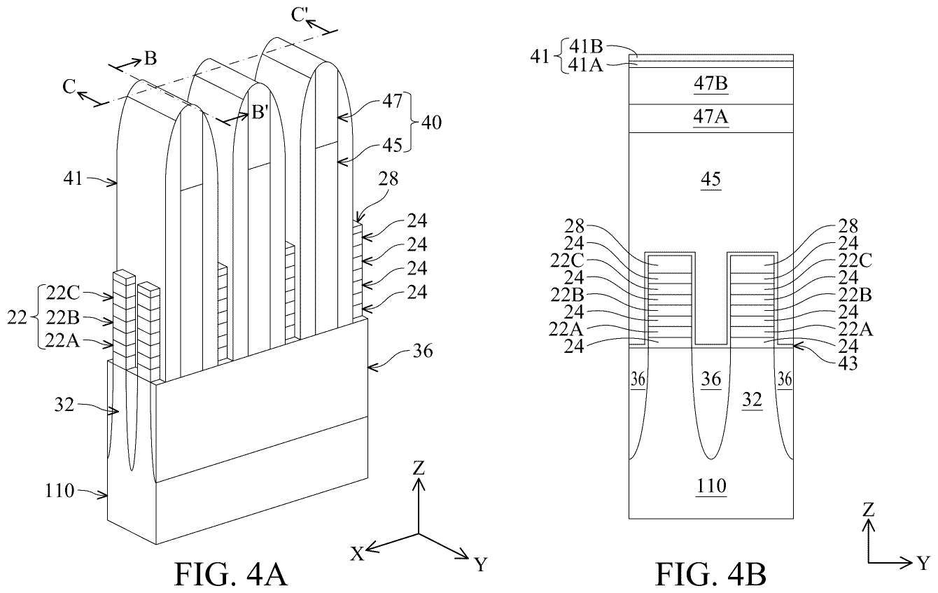

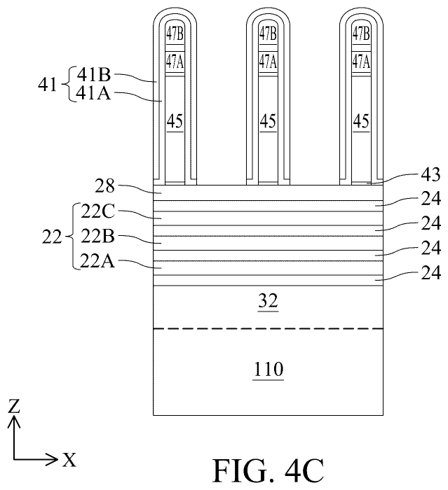

In FIGS. 4A-4C, dummy or sacrificial gate structures 40 are formed over the fins 32, the nanostructures 22, 24 and the hard mask structures 28, corresponding to act 1200 of FIG. 18. A dummy or sacrificial gate layer 45 is formed over the fins 32 and/or the nanostructures 22, 24. The sacrificial gate layer 45 may be or include materials that have a high etching selectivity relative to the isolation regions 36. The sacrificial gate layer 45 may be a conductive, semiconductive or non-conductive material and may be or include amorphous silicon, polycrystalline-silicon (polysilicon), poly-crystalline silicon-germanium (poly-SiGe), metallic nitrides, metallic silicides, metallic oxides, and metals. The sacrificial gate layer 45 may be deposited by physical vapor deposition (PVD), CVD, sputter deposition, or other techniques for depositing the selected material. A mask layer 47 is formed over the sacrificial gate layer 45, and may include, for example, silicon nitride, silicon oxynitride, or the like. In some embodiments, a gate dielectric layer or “liner layer” 43 is formed before the sacrificial gate layer 45 and between the sacrificial gate layer 45 and the fins 32 and/or the nanostructures 22, 24. In some embodiments, the liner layer 43 is or includes one or more dielectric materials, such as Si₃N₄, SiO₂, SiON, or the like, one or more semiconductors including Si, SiGe, combinations thereof, or the like. Thickness of the liner layer 43 may be in a range of about 0.5 nm to about 10 nm. In some embodiments, the mask layer 47 includes a first mask layer 47A in contact with the sacrificial gate layer 45, and a second mask layer 47B overlying and in contact with the first mask layer 47A. The first mask layer 47A may be or include the same or different material as that of the second mask layer 47B. In some embodiments, prior to forming the gate dielectric layer 43, the nanostructures 24 may be removed and then a dielectric layer or oxide layer may be gap filled in place of the nanostructures 24.

A spacer layer 41 is formed over sidewalls of the mask layer 47 and the sacrificial gate layer 45. As depicted in FIG. 4A, lower portions of the spacer layer 41 extend downward between adjacent stacks of nanostructures 22, 24 and may land on upper surfaces of the isolation regions 36. The spacer layer 41 is or includes an insulating material, such as SiCON, SiON, SiOF, Si₃N₄, SiO₂ or the like and may have a single-layer structure or a multi-layer structure including a plurality of dielectric layers, in accordance with some embodiments. The spacer layer 41 may be formed by depositing a spacer material layer (not shown) over the mask layer 47 and the sacrificial gate layer 45. Portions of the spacer material layer between sacrificial gate structures 40 are removed using an anisotropic etching process, in accordance with some embodiments. In some embodiments, as shown in detail in FIGS. 4B, 4C, the spacer layer 41 includes a first spacer layer 41A in contact with the nanostructure 22C, the gate dielectric layer 43, the sacrificial gate layer 45 and the first and second mask layers 47A, 47B. A second spacer layer 41B of the spacer layer 41 may be in contact with the first spacer layer 41A. The first spacer layer 41A may be or include the same or different material as that of the second spacer layer 41B. Thickness of the spacer layer 41 may be in a range of about 2 nm to about 20 nm.

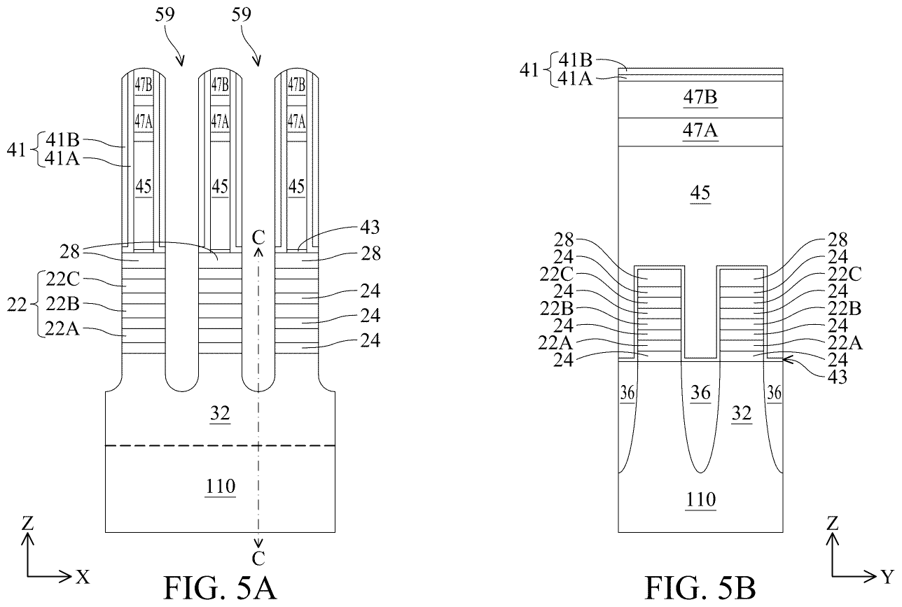

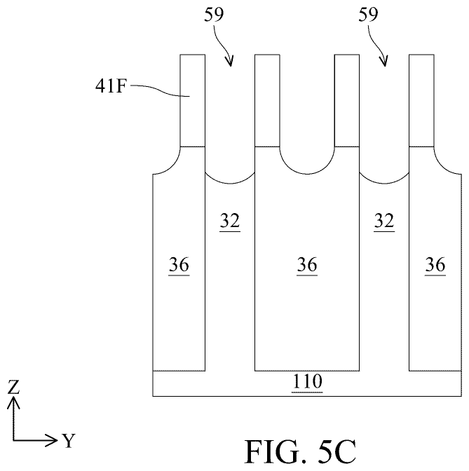

In FIGS. 5A-5C, source/drain openings 59 are formed by performing an etching process to etch the portions of protruding fins 32, hard mask structures 28 and/or nanostructures 22, 24 that are not covered by sacrificial gate structures 40. The recessing may be anisotropic, such that the portions of fins 32 directly underlying sacrificial gate structures 40 and the spacer layer 41 are protected and are not substantially etched. The top surfaces of the recessed fins 32 may be substantially coplanar with the top surfaces of the isolation regions 36, in accordance with some embodiments. The top surfaces of the recessed fins 32 may be lower than the top surfaces of the isolation regions 36, in accordance with some other embodiments, as depicted in FIGS. 5A and 5C. FIG. 5A depicts three vertical stacks of nanostructures 22, 24 following the etching process for simplicity. In general, the etching process may be used to form fewer or additional vertical stacks of nanostructures 22, 24 over fins 32 than those depicted. In some embodiments, the second mask layer 47B is exposed following the etching process, for example, due to removal of upper portions of the spacer layers 41A, 41B during the etching process. FIG. 5C depicts fin spacers 41F which are portions of the first and/or second spacer layers 41A, 41B that overlie the isolation regions 36 adjacent to respective fins 32.

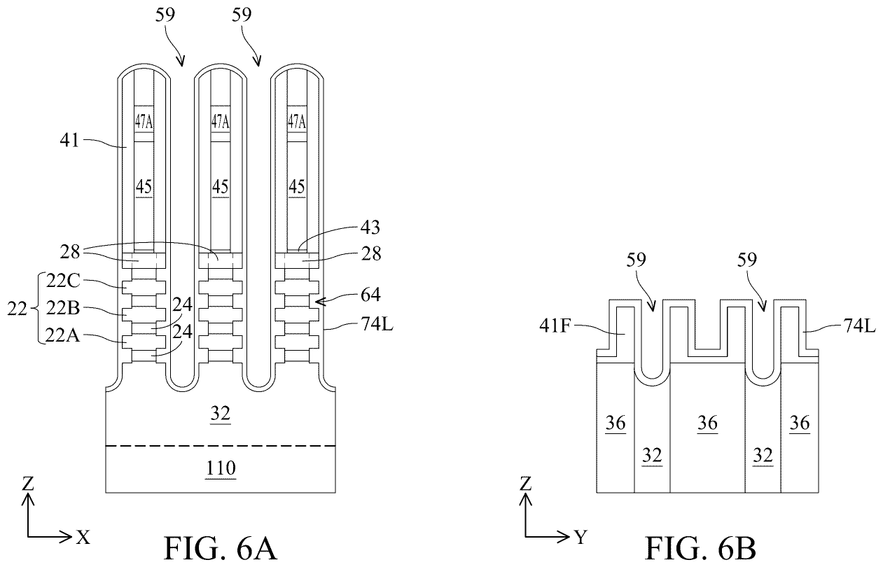

In FIGS. 6A and 6B, recesses 64 are formed by removing end portions of the nanostructures 24. For example, a selective etching process is performed to recess the end portions of the nanostructures 24 exposed by the source/drain openings 59 without substantially attacking the nanostructures 22 or thinning end portions of the nanostructures 22 slightly. After the selective etching process, recesses 64 are formed in the nanostructures 24 at locations where the removed end portions used to be. Then, following formation of the recesses 64, an inner spacer layer 74L is formed to fill (partially or entirely) the recesses in the nanostructures 22 formed by the previous selective etching process. The inner spacer layer 74L may be a suitable dielectric material, such as SiO₂, Si₃N₄, SiON, SiCN, SiCON or the like, formed by a suitable deposition method such as PVD, CVD, ALD, or the like.

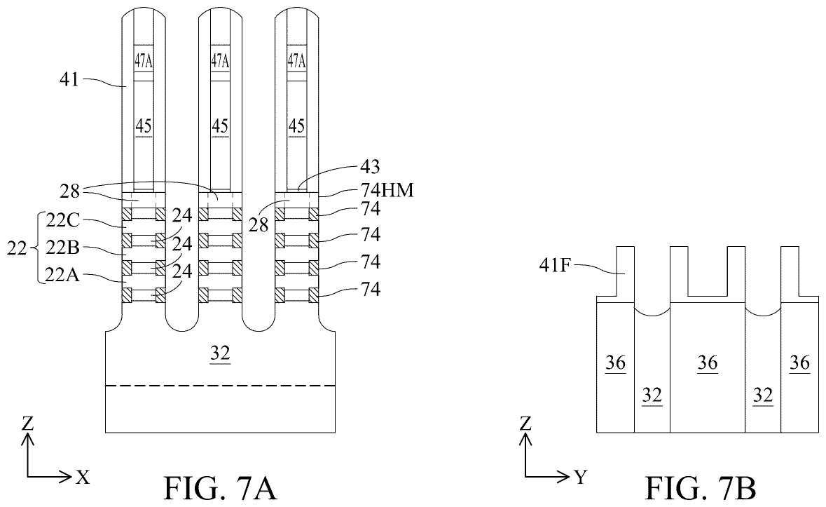

In FIGS. 7A and 7B, following formation of the inner spacer layer 74L, an etching process, such as an anisotropic etching process, is performed to remove portions of the inner spacer layer 74L disposed outside the recesses, for example, on sidewalls of the nanostructures 22 and the fins 32. The remaining portions of the inner spacer layer 74L (e.g., portions disposed inside the recesses in the nanostructures 24) form the inner spacers 74. Thickness of the inner spacers 74 may be in a range of about 1 nm to about 10 nm. The thickness may refer to thickness in the X-axis direction depicted in FIG. 7A, the Z-axis direction depicted in FIG. 7A, or both.

In the description of forming inner spacers 74 provided with reference to FIGS. 6A to 7B, the inner spacers 74 are formed in recesses 64 that are adjacent the nanostructures 24 between the channels 22 and also between the topmost channel 22C and the hard mask structure 28. In some embodiments, prior to forming the inner spacer layer 74L, the hard mask structures 28 may be recessed (e.g., end portions thereof removed) in the same or a different etching process to that which forms the recesses 64. Then, additional inner spacers can be formed immediately adjacent to the recessed hard mask structures 28 during the formation of the inner spacers 74 immediately adjacent to the recessed nanostructures 24. The inner spacers immediately adjacent to the hard mask structures 28 have different etch selectivity than the hard mask structures 28, which can be beneficial for providing electrical isolation between gate structures 200 that may replace the hard mask structures 28 and adjacent source/drains 82P, 82N. Positions of the recesses and inner spacers adjacent the hard mask structures 28 are depicted in FIGS. 6A and 7A by dashed lines.

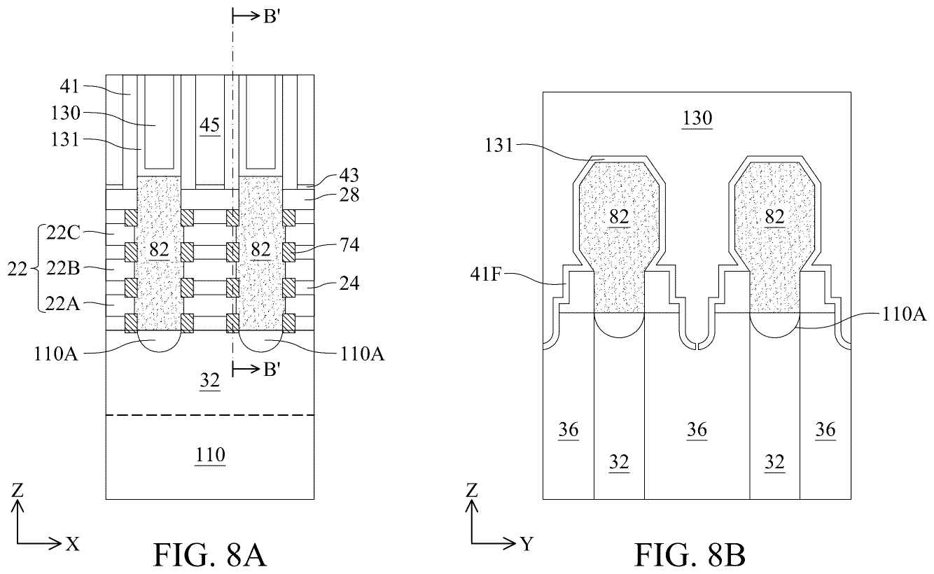

In FIG. 8A, a first semiconductor layer 110A is formed in the source/drain openings 59. The first semiconductor layer 110A is an undoped silicon layer in some embodiments that may be deposited or epitaxially grown on exposed surfaces of the fin 32. The deposition may include one or more operations, such as a CVD, which may be an ultra-high vacuum chemical vapor deposition (UHV-CVD), which allows for improved control of deposition rate and purity of the first semiconductor layer 110A. In some embodiments, precursor gases containing silicon may be introduced into a processing chamber, and a reaction therebetween forms the silicon material, which deposits into the source/drain openings 59. In some embodiments, the first semiconductor layer 110A has an upper surface that is at a level substantially coplanar with an upper surface of the fin 32.

In FIG. 8A, source/drain regions or “source/drains” 82 are formed. In the illustrated embodiment, the source/drain regions 82 are epitaxially grown from epitaxial material(s). In some embodiments, the source/drain regions 82 exert stress in the respective channels 22A, 22B, 22C, thereby improving performance. The source/drain regions 82 are formed such that each sacrificial gate structure 40 is disposed between respective neighboring pairs of the source/drain regions 82. In some embodiments, the spacer layer 41 separates the source/drain regions 82 from the sacrificial gate layer 45 by an appropriate lateral distance to prevent electrical bridging to subsequently formed gates of the resulting device. The source/drain regions 82 may be or include Si:B, Si:Ga, SiGe:B, SiGe:B:Ga, SiGe:Sn, SiGe:B:Sn or the like. The source/drain regions 82 may be or include SiP, SiAs, SiSb, SiPAs, SiP:As:Sb or the like. The source/drain regions 82 may exert a compressive or tensile strain in the channel regions. The source/drain regions 82 may have surfaces raised from respective surfaces of the first semiconductor layer 110A and may have facets. Neighboring source/drain regions 82 may merge in some embodiments to form a singular source/drain region 82 adjacent two neighboring fins 32.

In FIGS. 8A and 8B, following formation of the source/drain regions 82, the ILD 130 may be formed covering the source/drain regions 82 and abutting the spacer layer 41. In some embodiments, the ESL 131 is formed prior to forming the ILD 130. The ESL 131 may be formed by depositing a conformal thin layer of a dielectric material different from that of the ILD 130, such as one or more of SiN, SiCN, SiC, SiOC, SiOCN, HfO₂, ZrO₂, ZrAlOx, HfAlOx, HfSiOx, Al2O3, or other suitable material. Following deposition of the ESL 131, the ILD 130 may be deposited by a suitable process, such as a blanket deposition process, including PVD, CVD, ALD, or the like. The material of the ILD 130 may include silicon dioxide or a low-k dielectric material (e.g., a material having a dielectric constant (k-value) lower than the k-value (about 3.9) of silicon dioxide). The low-k dielectric material may include silicon oxynitride, phosphosilicate glass (PSG), borosilicate glass (BSG), borophosphosilicate glass (BPSG), undoped silicate glass (USG), fluorinated silicate glass (FSG), silicon oxycarbide (SiOₓC_{y}), Spin-On-Glass (SOG) or a combination thereof. The ILD 130 may be deposited by spin-on coating, CVD, Flowable CVD (FCVD), PECVD, PVD, or another deposition process.

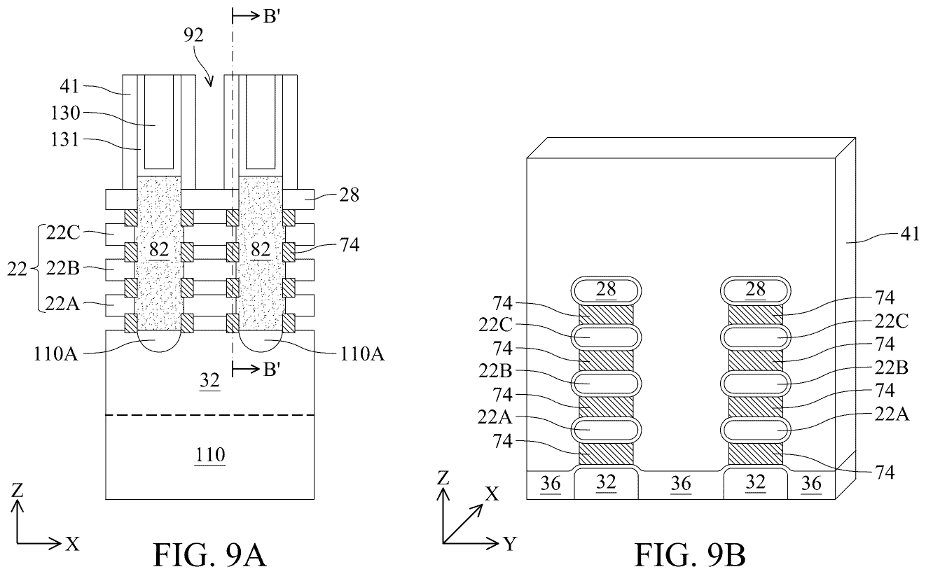

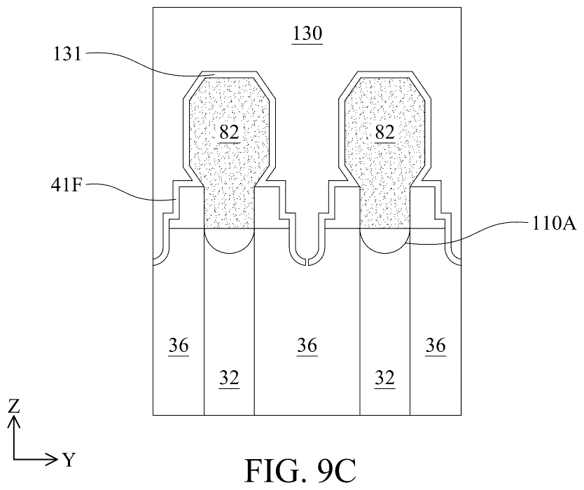

FIGS. 9A-15F are views depicting formation of a gate structure 200 that has a high-k dielectric layer 600S having reduced size via a selective etching process that removes portions of a high-k dielectric layer 600 from a side surface of the spacer layer 41.

In FIGS. 9A-9C, following formation of the source/drains 82, the ESL 131 and the ILD 130, a planarization process, such as a chemical mechanical polishing (CMP) process, may be performed on the ILD 130 and the ESL 131. The hard masks 47A, 47B and portions of the gate spacers 41 are also removed in the planarization process. After the planarization process, the sacrificial gate layers 45 are exposed. The top surfaces of the ILD 130 and the ESL 131 may be coplanar with the top surfaces of the sacrificial gate layers 45 and the gate spacers 41.

Next, as depicted in FIGS. 9A-9C, the sacrificial gate layer 45 is removed in an etching process, so that openings 92 are formed. In some embodiments, the sacrificial gate layer 45 is removed by an anisotropic dry etch process. For example, the etching process may include a wet etch process or a dry etch process using reaction gas(es) that selectively etch the sacrificial gate layer 45 without etching the spacer layer 41. The sacrificial gate dielectric 43, when present, may be used as an etch stop layer when the sacrificial gate layer 45 is etched. The sacrificial gate dielectric 43 may then be removed after the removal of the sacrificial gate layer 45. FIG. 9B is a perspective view along cross-sectional line B′-B′ of FIG. 9A.

The nanostructures 24 are then removed to release the nanostructures 22, corresponding to act 1300 of FIG. 18. After the nanostructures 24 are removed, the nanostructures 22 form a plurality of nanosheets that extend horizontally (e.g., parallel to a major upper surface of the substrate 110, such as in the X-Y plane). In some embodiments, the nanostructures 24 are removed by a selective etching process using an etchant that is selective to the material of the nanostructures 24, such that the nanostructures 24 are removed without substantially attacking the nanostructures 22. In some embodiments, the etching process is an isotropic etching process using an etching gas, and optionally, a carrier gas, where the etching gas comprises F2 and HF, and the carrier gas may be an inert gas such as Ar, He, N2, combinations thereof, or the like.

In some embodiments, the nanostructures 24 are removed and the nanostructures 22 are patterned to form channel regions of both PFETs and NFETs. However, in some embodiments the nanostructures 24 may be removed and the nanostructures 22 may be patterned to form channel regions of NFETs, and nanostructures 22 may be removed and the nanostructures 24 may be patterned to form channel regions of PFETs. In some embodiments, the nanostructures 22 may be removed and the nanostructures 24 may be patterned to form channel regions of NFETs, and the nanostructures 24 may be removed and the nanostructures 22 may be patterned to form channel regions of PFETs. In some embodiments, the nanostructures 22 may be removed and the nanostructures 24 may be patterned to form channel regions of both PFETs and NFETs.

In some embodiments, the nanosheets 22 are reshaped (e.g. thinned) by a further etching process to improve gate fill window. The reshaping may be performed by an isotropic etching process selective to the nanosheets 22. After reshaping, the nanosheets 22 may exhibit the dog bone shape in which middle portions of the nanosheets 22 are thinner than peripheral portions of the nanosheets 22 along the X direction.

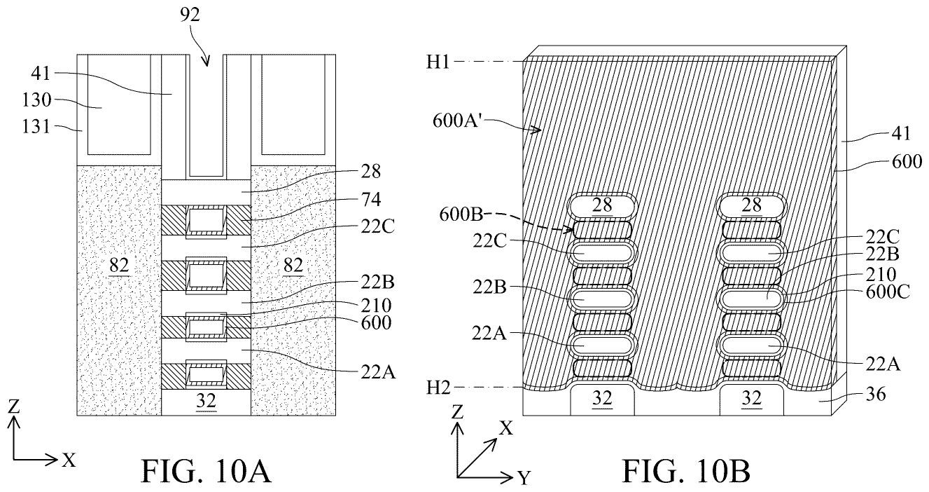

In FIGS. 10A-15G, a gate structure 200 is formed in the gate opening 92. To provide context for understanding the embodiments in which the high-k dielectric layer 600 is reduced to form the reduced high-k dielectric layer 600S, description is now provided of the materials and processes for forming various layers of the gate structure 200 with reference to FIG. 16.

FIG. 16 is a detailed view of a portion of the gate structure 200 between the channels 22B and 22C. The gate structure 200 generally includes the interfacial layer (IL, or “first IL” below) 210, at least one gate dielectric layer 600, the work function metal layer 900, and the gate fill layer 290. In some embodiments, each replacement gate 200 further includes at least one of a second interfacial layer 240 or a second work function layer 700.

With reference to FIG. 16, in some embodiments, the first IL 210 includes an oxide of the semiconductor material of the substrate 110, e.g. silicon oxide. In other embodiments, the first IL 210 may include another suitable type of dielectric material. The first IL 210 has a thickness in a range between about 5 angstroms and about 50 angstroms. The first IL 210 can be formed by thermal oxidation, CVD, ALD, or the like.

Still referring to FIG. 16, the gate dielectric layer 600 is formed over the first IL 210. In some embodiments, an atomic layer deposition (ALD) process is used to form the gate dielectric layer 600 to control thickness of the deposited gate dielectric layer 600 with precision. In some embodiments, the ALD process is performed using between about 40 and 80 deposition cycles, at a temperature range between about 200 degrees Celsius and about 300 degrees Celsius. In some embodiments, the ALD process uses HfCl4 and/or H2O as precursors. Such an ALD process may form the first gate dielectric layer 220 to have a thickness in a range between about 10 angstroms and about 100 angstroms.

In some embodiments, the gate dielectric layer 600 includes a high-k dielectric material, which may refer to dielectric materials having a high dielectric constant that is greater than a dielectric constant of silicon oxide (k˜3.9). Exemplary high-k dielectric materials include HfO₂, HfSiO, HfSiON, HfTaO, HfTiO, HfZrO, ZrO₂, Ta₂O₅, or combinations thereof. In other embodiments, the gate dielectric layer 600 may include a non-high-k dielectric material such as silicon oxide. In some embodiments, the gate dielectric layer 600 includes more than one high-k dielectric layer, of which at least one includes dopants, such as lanthanum, magnesium, yttrium, or the like, which may be driven in by an annealing process to modify threshold voltage of the nanostructure devices 20A, 20B. The gate dielectric layer 600 is reduced to form a reduced gate dielectric layer 600S in embodiments of the disclosure.

With further reference to FIG. 16, an optional second IL 240 is formed on the gate dielectric layer 600 (or reduced gate dielectric layer 600S), and the second work function layer 700 is formed on the second IL 240. The second IL 240 promotes better metal gate adhesion on the gate dielectric layer 600. In many embodiments, the second IL 240 further provides improved thermal stability for the gate structure 200 and serves to limit diffusion of metallic impurities from the work function metal layer 900 and/or the work function barrier layer 700 into the gate dielectric layer 600. In some embodiments, formation of the second IL 240 is accomplished by first depositing a high-k capping layer (not illustrated for simplicity) on the gate dielectric layer 600. The high-k capping layer comprises one or more of the following: HfSiON, HfTaO, HfTiO, HfTaO, HfAlON, HfZrO, or other suitable materials, in various embodiments. In one embodiment, the high-k capping layer comprises titanium silicon nitride (TiSiN). In some embodiments, the high-k capping layer is deposited by an ALD using about 40 to about 100 cycles at a temperature of about 400 degrees C. to about 450 degrees C. A thermal anneal is then performed to form the second IL 240, which may be or comprise TiSiNO, in some embodiments. Following formation of the second IL 240 by thermal anneal, an atomic layer etch (ALE) with artificial intelligence (AI) control may be performed in cycles to remove the high-k capping layer while substantially not removing the second IL 240. Each cycle may include a first pulse of WCl₅, followed by an Ar purge, followed by a second pulse of O₂, followed by another Ar purge. The high-k capping layer is removed to increase gate fill window for further multiple threshold voltage tuning by metal gate patterning.

Further in FIG. 16, after forming the second IL 240 and removing the high-k capping layer, the work function barrier layer 700 is optionally formed on the intermediate gate structure 200 (e.g., on the second ILD 240 or the reduced high-k dielectric layer 600S), in accordance with some embodiments. The work function barrier layer 700 is or comprises a metal nitride, such as TiN, WN, MON, TaN, or the like. In a specific embodiment, the work function barrier layer 700 is TIN. The work function barrier layer 700 may have thickness ranging from about 5 A to about 20 A. Inclusion of the work function barrier layer 700 provides additional threshold voltage tuning flexibility. In general, the work function barrier layer 700 increases the threshold voltage for NFET transistor devices and decreases the threshold voltage (magnitude) for PFET transistor devices.

The work function metal layer 900, which may include at least one of an N-type work function metal layer, an in-situ capping layer, or an oxygen blocking layer, is formed on the work function barrier layer 700, in some embodiments. The N-type work function metal layer is or comprises an N-type metal material, such as TiAlC, TiAl, TaAlC, TaAl, or the like. The N-type work function metal layer may be formed by one or more deposition methods, such as CVD, PVD, ALD, plating, and/or other suitable methods, and has a thickness between about 10 A and 20 A. The in-situ capping layer is formed on the N-type work function metal layer. In some embodiments, the in-situ capping layer is or comprises TIN, TiSiN, TaN, or another suitable material, and has a thickness between about 10 A and 20 A. The oxygen blocking layer is formed on the in-situ capping layer to prevent oxygen diffusion into the N-type work function metal layer, which would cause an undesirable shift in the threshold voltage. The oxygen blocking layer is formed of a dielectric material that can stop oxygen from penetrating to the N-type work function metal layer, and may protect the N-type work function metal layer from further oxidation. The oxygen blocking layer may include an oxide of silicon, germanium, SiGe, or another suitable material. In some embodiments, the oxygen blocking layer is formed using ALD and has a thickness between about 10 A and about 20 A.

FIG. 16 further illustrates the metal core layer or “metal layer” 290. In some embodiments, a glue layer (not separately illustrated) is formed between the oxygen blocking layer of the work function metal layer and the metal core layer 290. The glue layer may promote and/or enhance the adhesion between the metal core layer 290 and the work function metal layer 900. In some embodiments, the glue layer may be formed of a metal nitride, such as TIN, TaN, MON, WN, or another suitable material, using ALD. In some embodiments, thickness of the glue layer is between about 10 A and about 25 A. The metal core layer 290 may be formed on the glue layer, and may include a conductive material such as tungsten, cobalt, ruthenium, iridium, molybdenum, copper, aluminum, or combinations thereof. In some embodiments, the metal core layer 290 may be deposited using methods such as CVD, PVD, plating, and/or other suitable processes. In some embodiments, a seam 510, which may be an air gap, is formed in the metal core layer 290 vertically between the channels 22A, 22B, 22C. In some embodiments, the metal core layer 290 is conformally deposited on the work function metal layer 900. The seam 510 may form due to sidewall deposited film merging during the conformal deposition. In some embodiments, the seam 510 is not present between the neighboring channels 22A, 22B, 22C.

In some embodiments, one or more of metal layers including the core layer 290 and the work function layers 700, 900 in PFET devices can include Ti, Al, Zn, W, Nb, Co and the like and total thickness of the combination of metal layers on the gate dielectric layer 600 may be in a range of about 0.5 nm to about 20 nm. In some embodiments, one or more of metal layers including the core layer 290 and the work function layers 700, 900 in NFET devices can include Ti and/or Al and the like and total thickness of the combination of metal layers on the gate dielectric layer 600 may be in a range of about 0.5 nm to about 20 nm. In some embodiments, one or more of the second IL 240, the work function layer 700 and the work function layer 900 can be omitted.

In FIGS. 10A and 10B, an interfacial layer or “IL” 210 is formed on exposed surfaces of the channels 22 and the fin 32, similar to described with reference to FIG. 16. In some embodiments, the IL 210 includes an oxide of the semiconductor material of the channels 22 and/or the substrate 110, and may include SiO₂, SiON, HfSiOₓ, LaSiOₓ, YSiOₓ, AlSiOₓ or the like. The IL 210 may be formed by chemical oxidation, thermal oxidation, ALD growth, or the like. The IL 210 on the channels 22 may be a different material than the IL 210 on the fin 32 when the channels 22 are a different material than the fin 32. In some embodiments, the IL 210 has thickness in a range of about 5 angstroms to about 50 angstroms. Generally, the IL 210 is not present on (e.g., does not grow on) the hard mask structure 28 or the spacer layer 41, as depicted in FIGS. 10A and 10B.

Following formation of the IL 210, the high-k gate dielectric layer 600 is formed on exposed surfaces of the spacer layer 41, the hard mask layer 28, the inner spacers 74 (also depicted in phantom in FIG. 10B) and the IL 210 (e.g., on the channels 22 and the fin 32), corresponding to act 1400 of FIG. 18. The high-k gate dielectric layer 600 may be formed by one or more non-selective growth processes, such as CVD, ALD or the like, and may include one or more dielectric materials, such as HfO₂, ZrO₂, La₂O₃, Al₂O₃, HfZrOₓ, HfLaOₓ, HfAlOₓ, HfYOₓ, HfSiOₓ, HfSiON or the like. Thickness of the high-k gate dielectric layer 600 may be in a range of about 0.5 nm to about 5 nm. The high-k dielectric layer 600 may completely or substantially completely cover the side surface of the gate spacer 41, as depicted in FIG. 10B. The gate dielectric layer 600 can extend from a first level H1 above the nanostructure channels to a second level H2 below the nanostructure channels. The first level H1 can be an upper surface of the gate spacer 41, the ILD 130 and/or the ESL 131. The second level H2 can be an upper surface of the isolation regions 36 and/or the fin 32. The high-k dielectric layer 600 includes portions 600A′ that cover the side surface of the gate spacer 41, portions 600B that cover the inner spacers 74 and portions 600C that cover the channels 22 and the hard mask structure 28.

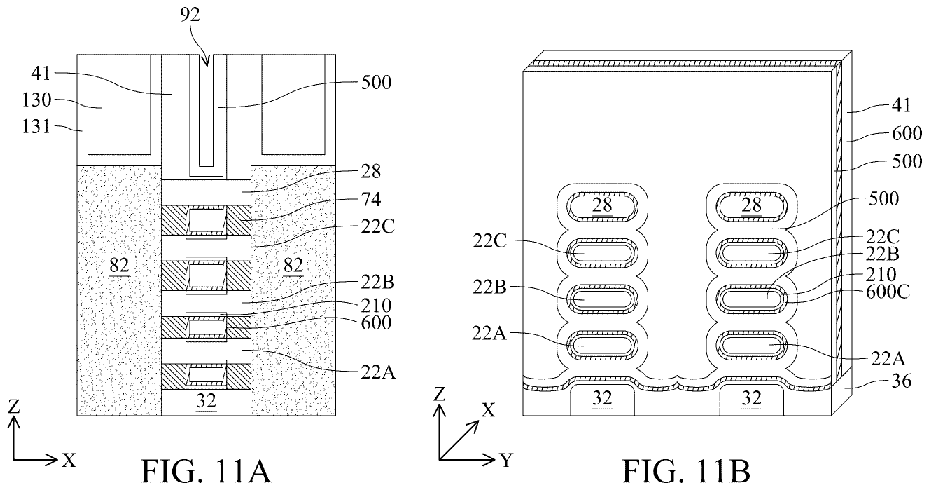

In FIGS. 11A and 11B, following formation of the high-k gate dielectric layer 600, a sacrificial interposer layer 500 is formed on the high-k dielectric layer 600, such as on the spacer layer 41, the hard mask layer 28, the inner spacers 74, the channels 22 and the fin 32. The sacrificial interposer layer 500 can be or include a material that is suitable for performing selective growth thereon. In some embodiments, the sacrificial interposer layer 500 includes TiN, Si, Ge, W, Al₂O₃ or the like. The material of the sacrificial interposer layer 500 is or includes a material that is suitable for performing selective growth of the same material or a different material thereon. For example, tungsten or TiN can be grown on exposed surfaces of TiN. In another example, TiN can be grown on exposed surfaces of TiN or Al₂O₃. In yet another example, Si, SiGe or W can be grown on exposed surfaces of Si. The sacrificial interposer layer 500 may be formed by a suitable growth process, such as CVD, ALD or the like and merges in between the channels 22 to protect portions 600B of the high-k dielectric layer 600 on the inner spacers 74 and portions 600C of the high-k dielectric layer 600 on the channels 22 and the hard mask structure 28. The sacrificial interposer layer 500 may or may not merge above the hard mask structure 28. In the view of FIG. 11A, the sacrificial interposer layer 500 does not merge above the hard mask structure 28, resulting in thin layers of the sacrificial interposer layer 500 being present on the gate spacer 41 on either side of the gate opening 92. Thickness of the sacrificial interposer layer may be in a range of about 1 nm to about 10 nm.

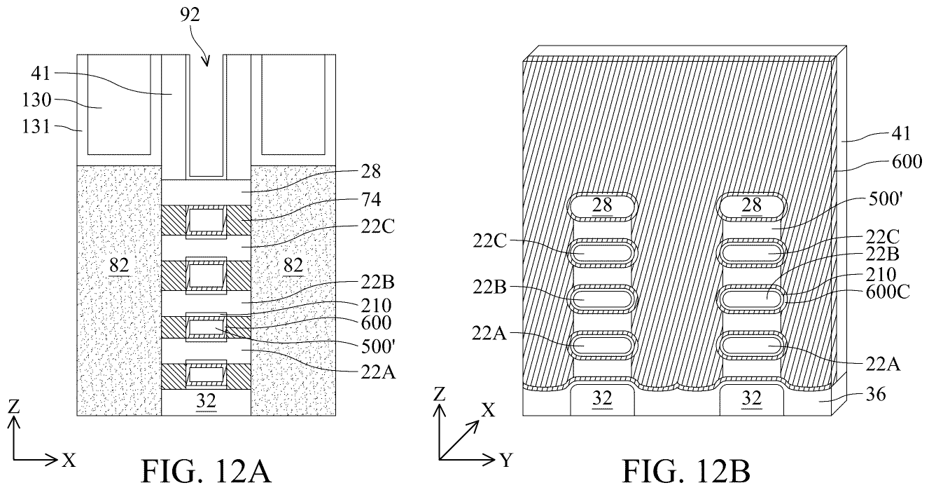

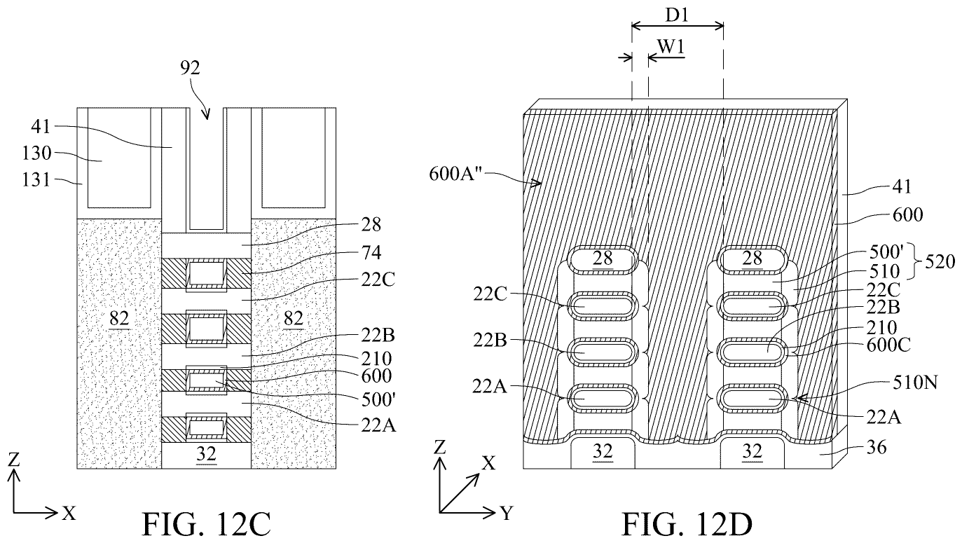

In FIGS. 12A-12D, following deposition of the sacrificial interposer layer 500, sacrificial plugs or “protective plugs” 500′ and protective structures 510 are formed that can be used as a mask 520 during reduction of area of the high-k gate dielectric layer 600 to form the reduced high-k gate dielectric layer 600S.

In FIGS. 12A and 12B, following deposition of the sacrificial interposer layer 500, sacrificial materials of the sacrificial interposer layer 500 are trimmed back, stopping on the portions 600C of the high-k dielectric layer 600, to remove the sacrificial materials from the side surface of the gate spacer 41 by dry or wet etching. Sacrificial plugs 500′ remain between the nanostructures 22 and between the nanostructure 22C and the hard mask structure 28 following the removal operation. Etch of the sacrificial materials of the sacrificial interposer layer 500 that selectively stops on the high-k dielectric layer 600 can be via an etching operation that can include SC1, SC2, HCl, NH₄OH, H₂O₂, combinations thereof or the like. Following the etching operation, portions of the high-k dielectric layer 600C on ends of the nanostructures 22 and ends of the hard mask structure 28 can be exposed. The upper surface of the hard mask structure 28 can also be exposed following the etching operation.

Then, in FIGS. 12C and 12D, following trimming of the sacrificial interposer layer 500 to form the sacrificial plugs 500′, the protective structures 510 are grown on exposed surfaces of the sacrificial plugs 500′ to protect the exposed side surfaces of the portion 600C of the high-k dielectric layer 600 on the channels 22. The growth on the sacrificial plugs 500′ of the protective structures 510 may be selective, such that the growth occurs on the exposed surfaces of the sacrificial plugs 500′ but not on exposed surfaces of the high-k dielectric layer 600, such as the channel portions 600C thereof. The selective growth of the protective structures 510 may be or include an ALD or CVD. The selective growth may form a second material on first material of the sacrificial plugs 500′. For example, the first material may be TiN and the second material may be W or TiN. In another example, the first material may be Al₂O₃ and the second material may be TiN. In yet another example, the first material may be Si and the second material may be Si, SiGe or W. As can be understood from the above examples, the second material may be the same as or different than the first material. Growth of the protective structures 510 may initially proceed laterally outward from the sacrificial plugs 500′, such as in the Y-axis direction. Then, initially grown portions of the protective structures 510 may begin growing along the vertical Z-axis direction and eventually merge adjacent the ends of the channels 22, resulting in the side surfaces of the portions 600C of the high-k dielectric layer 600 being covered. In some embodiments, as depicted in FIG. 12D, notches 510N may be present in the protective structures 510 adjacent the channels 22 due to how the protective structures 510 merge near the channels 22. Due to the notches 510N, the protective structures 510 may have non-uniform width in the Y-axis direction along their height in the Z-axis direction. In some embodiments, width W1 of the protective structures 510 may be in a range of about 1 nm to about 20 nm. In some embodiments, the width W1 of the protective structures 510 may be measured as a percentage of distance D1 between neighboring stacks of channels 22, as depicted in FIG. 12D. In some embodiments, the percentage is in a range of about 1% to about 40%. For example, the distance D1 may be in a range of about 18 nm to about 100 nm. In this example, when the distance D1 is about 18 nm, the width W1 being about 1 nm results in a percentage of about 5% to about 6%.

Following formation of the mask 520 including the sacrificial plugs 500′ and the protective structures 510, portions 600A″ of the high-k dielectric layer 600 may be exposed in the gate trench 92. The portions 600A″ are slightly smaller than the portions 600A′ described with reference to FIGS. 10A and 10B due to presence of the protective structure 510 partially covering portions of the high-k dielectric layer 600 between the stacks of channels 22.

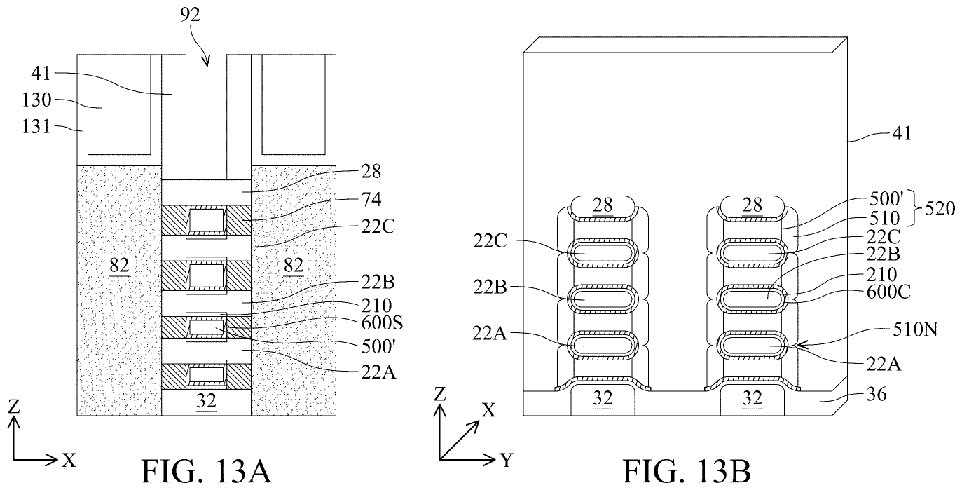

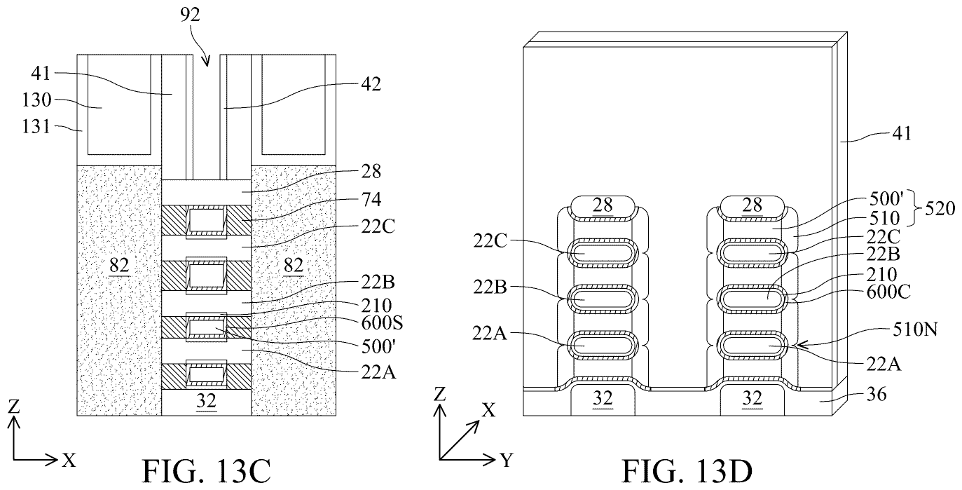

In FIGS. 13A and 13B, following formation of the mask 520 including the sacrificial plugs 500′ and the protective structures 510, exposed portions 600A″ of the high-k dielectric layer 600 are removed from on the gate spacer 41, corresponding to act 1500 of FIG. 18. Removal of the exposed portions 600A″ of the high-k dielectric layer 600 can be via a selective removal operation that removes material of the high-k dielectric layer 600 from the sidewall of the gate spacer 41, while keeping portions 600C of the high-k dielectric layer 600 on the channels 22 that are protected by the mask 520 including the sacrificial plugs 500′ and the protective structures 510. The removal operation can include high etching selectivity between material of the high-k dielectric layer 600 and the protective structure 510, such as HF-based or H₂SO₄-based wet etching for Si and HfO₂, HF-based or NF₃-based dry etching for TIN and HfO₂, and the like. The removal operation can remove the exposed portions 600A″ on the sidewall of the gate spacer 41 and may remove portions of the high-k dielectric layer 600C on upper surfaces of the hard mask structures 28. As depicted in FIGS. 13A and 13B, the removal operation may additionally remove material of the high-k dielectric layer 600 overlying the isolation structures 36, such that upper surfaces of the isolation structures 36 are exposed in the gate opening 92.

In some embodiments, as depicted in FIGS. 13C and 13D, following removal of the portion 600A″ of the high-k dielectric layer 600, a low-k dielectric spacer layer 42 may be formed on the exposed surfaces of the gate spacer 41 and the isolation structures 36. The low-k dielectric spacer layer 42 may be or include a low-k dielectric material, such as SiO, SiOC, SiN, organosilicate glass (OSG) or the like. The low-k dielectric spacer layer 42 may be formed via a suitable deposition operation, such as a PVD, CVD, ALD or the like. Following formation of the low-k dielectric material, which may form a thin conformal layer on the gate spacer 41, the isolation structures 36 and the upper surface of the hard mask structure 28, an anisotropic etch may be performed that removes material of the low-k dielectric spacer layer 42 from the upper surface of the hard mask structure 28. Forming the low-k dielectric spacer layer 42 prior to removal of the mask 520 can allow the mask 520 to protect the spaces between the channels 22 during formation of the low-k dielectric spacer layer 42 and prevent formation of the low-k dielectric spacer layer 42 between the channels 22. This can be beneficial to increase gate fill window for deposition of one or more layers of the gate structure 200 following formation of the reduced high-k dielectric layer 600S. Formation of the low-k dielectric spacer layer 42 can be beneficial to lower effective capacitance and increase gate-to-source/drain-contact reliability via reduced leakage. In embodiments in which the low-k dielectric spacer layer 42 is not formed, dimension shrinking may be improved due to increased space between the gate spacers 41 by removal of the high-k dielectric layer 600 therefrom. In some embodiments in which the low-k dielectric spacer layer 42 is not formed, gate resistance (Rg) can be reduced due to increased volume between the gate spacers 41 by removal of the high-k dielectric layer 600 therefrom.

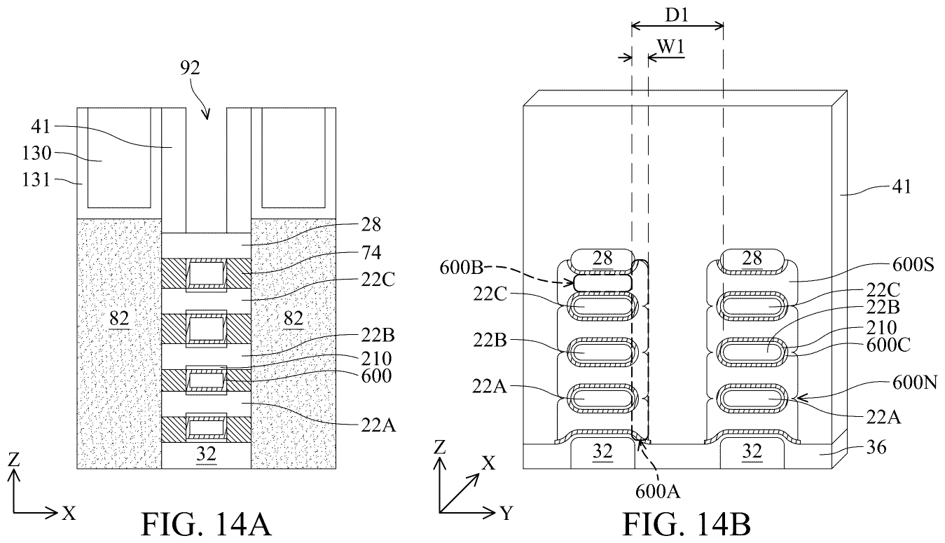

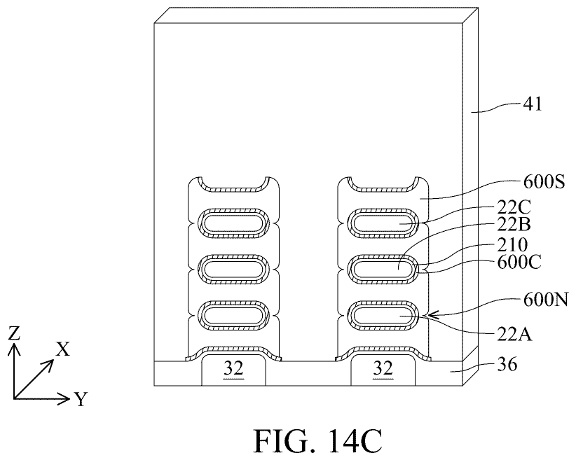

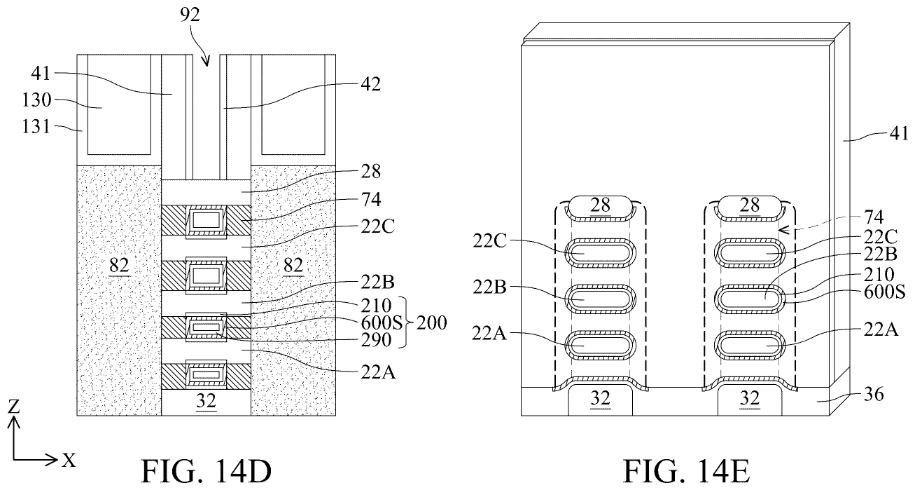

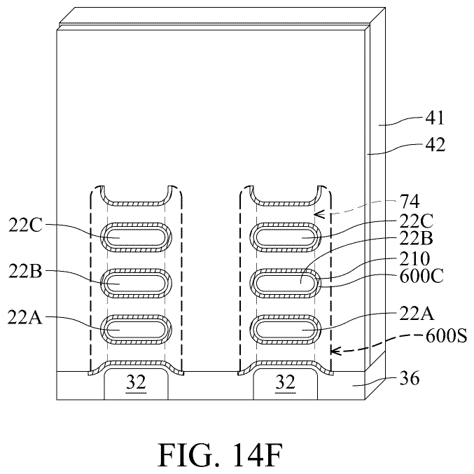

In FIGS. 14A-14F, following reduction in size of the high-k dielectric layer 600 to form the reduced high-k dielectric layer 600S, and optionally following formation of the low-k dielectric spacer layer 42 discussed with reference to FIGS. 13C and 13D, the mask 520 may be removed. The protective structure 510 and sacrificial plugs 500′ may be stripped by wet or dry etching that stops on the reduced high-k dielectric layer 600S, which may include SC1, SC2, HCl, NH₄OH, H₂O₂, combinations thereof or the like. As depicted in FIGS. 14A and 14B, the reduced high-k dielectric layer 600S remains on the nanostructures 20 and the inner spacers 74.

As depicted in FIGS. 14A and 14B, the reduced high-k dielectric layer 600S can have gate spacer portions 600A on the gate spacers 41, inner spacer portions 600B on the inner spacers 74 and notches 600N that inherit profile of the mask 520. Due to the notches 600N, the gate spacer portions 600A may have non-uniform width in the Y-axis direction along their height in the Z-axis direction. In some embodiments, width W1 of the gate spacer portions 600A may be in a range of about 1 nm to about 20 nm. In some embodiments, the width W1 of the gate spacer portions 600A may be measured as a percentage of distance D1 between neighboring stacks of channels 22, as depicted in FIG. 14B. In some embodiments, the percentage is in a range of about 1% to about 40%. For example, the distance D1 may be in a range of about 18 nm to about 100 nm. In this example, when the distance D1 is about 18 nm, the width W1 being about 1 nm results in a percentage of about 5% to about 6%. In some embodiments, the reduced high-k dielectric layer 600S can cover a portion of surface area of the side surface of the gate spacer 41. In some embodiments, the portion can be measured as a percentage of the surface area of the gate spacer 41. For example, the portion of the gate spacer 41 covered by the reduced high-k dielectric layer 600S can be in a range of about 0.5% to about 50%. In some embodiments, the portion is in a range of about 5% to about 40%.

In FIG. 14C, following removal of the mask 520, the hard mask structures 28 may be removed. Etching processes for removing the hard mask structures 28 can include wet chemical etching using hydrofluoric acid, hot phosphoric acid, plasma etching with CF₄/CHF₃, reactive ion etching (RIE) using fluorine-based or chlorine-based chemistries, and the like. The etching process can remove the hard mask structures 28 without substantially attacking the high-k dielectric layer 600S, the isolation regions 36 and the gate spacers 41. In the embodiment depicted in FIG. 14C, the upper surface of the high-k dielectric layer 600C on the hard mask structure 28 can be exposed following removal of the hard mask structure 28.

In FIGS. 14D-14F, the low-k dielectric spacer layer 42 is formed following removal of the mask 520. Formation of the low-k dielectric spacer layer 42 is similar in most respects to that described with reference to FIGS. 13C and 13D. Because the low-k dielectric spacer layer 42 is formed with the mask 520 not in place between the channels 22, the low-k dielectric spacer layer 42 can be deposited on the high-k dielectric layer 600C between the channels 22, as depicted in FIG. 14D. FIG. 14F depicts that the low-k dielectric spacer layer 42 can be present on portions of the gate spacer 41 exposed following removal of the hard mask structures 28.

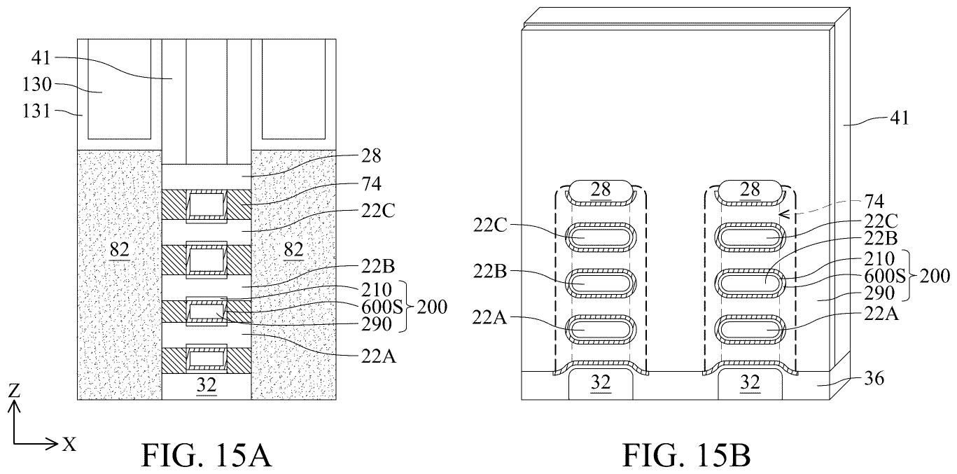

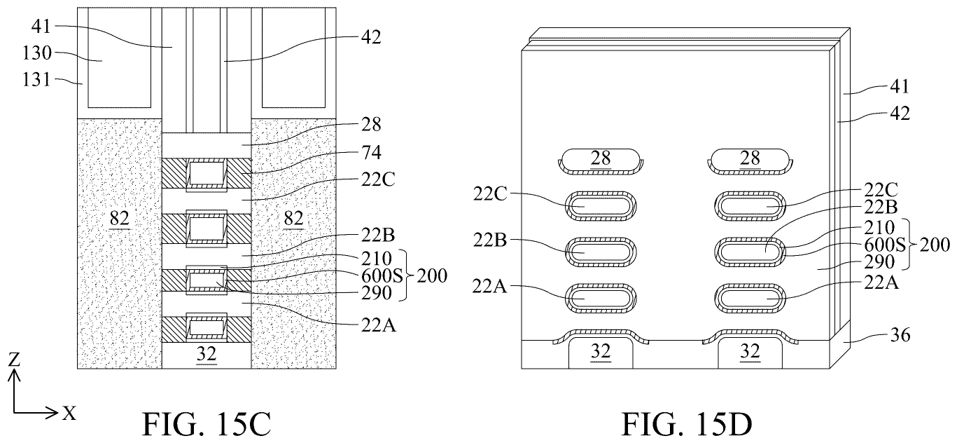

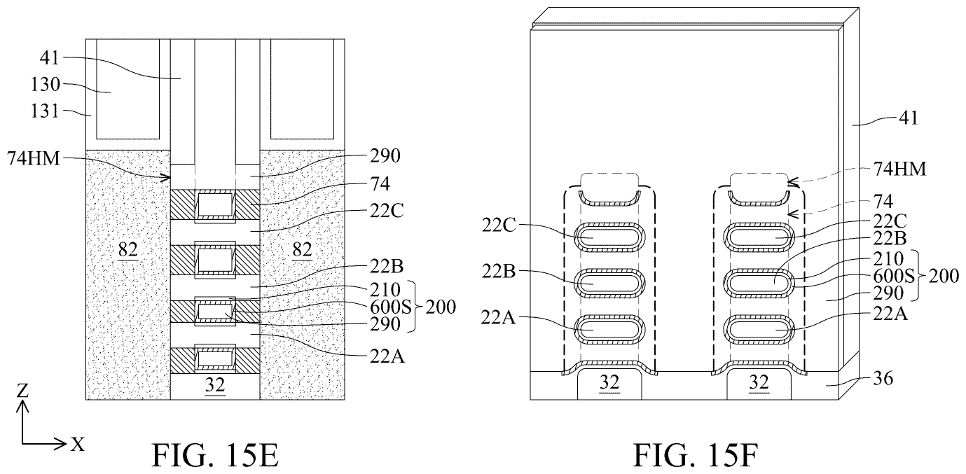

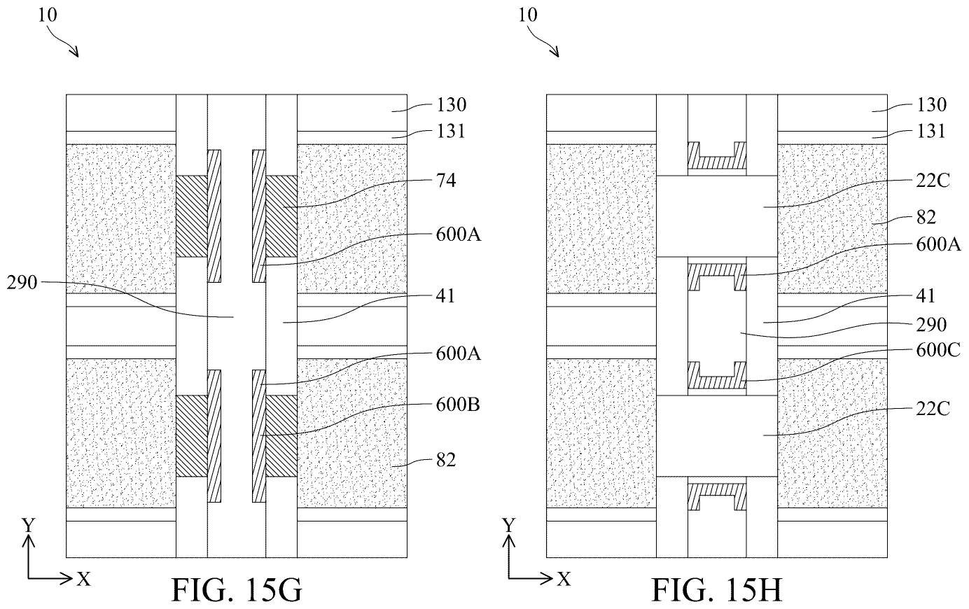

In FIGS. 15A-15I, following removal of the mask 520 and optionally following formation of the low-k dielectric spacer layer 42, one or more additional layers of the gate structure 200 including the conductive layer 290 are formed in the gate openings 92, corresponding to act 1600 of FIG. 18. The conductive layer 290 is depicted in FIG. 15A. Additional layers, such as the second IL 240, the work function layers 700, 900 described with reference to FIG. 16, or a combination thereof may be between the conductive layer 290 and the reduced high-k dielectric layer 600S and between the conductive layer 290 and the gate spacer 41 in regions in which the reduced high-k dielectric layer 600S is not present. FIG. 15G is a plan view taken in the X-Y plane through the inner spacers 74 of FIGS. 15A and 15B. FIG. 15H is a plan view taken in the X-Y plane through the channels 22C of FIGS. 15A and 15B. Due to reduction in area of the high-k dielectric layer 600 to form the reduced high-k dielectric layer 600S including the portions 600A, 600B that expose the side surface of the gate spacer 41, the conductive layer 290 may be immediately adjacent or in direct contact with the gate spacer 41 between the portions 600A. As depicted in FIG. 15G, because the reduced high-k dielectric layer 600S is in place, the metal layer 290 may be in direct contact with exposed portions of the gate spacer 41, such as portions of the gate spacer 41 not covered by the inner spacer portions 600B and the gate spacer portions 600A of the reduced high-k dielectric layer 600S. In some embodiments, as described with reference to FIG. 16, additional layers may be between the metal layer 290 and the gate spacer 41. For example, the second IL 240, the second work function layer 700, the work function tuning layer 900, the optional glue layer, or a combination thereof, can be present between the metal layer 290 and the gate spacer 41 without the reduced high-k dielectric layer 600S therebetween. For example, the second IL 240 may be in direct contact with the gate spacer 41. In another example, the second work function layer 700 may be in direct contact with the gate spacer 41. In yet another example, the work function tuning layer 900 may be in direct contact with the gate spacer 41.

FIGS. 15C and 15D depict embodiments in which the low-k dielectric spacer layer 42 is present on portions of the gate spacer 41 exposed by the reduced high-k dielectric layer 600S. FIG. 15I is a plan view taken in the X-Y plane through the inner spacers 74 of FIGS. 15C and 15D. In embodiments in which the low-k dielectric spacer layer 42 is present, the conductive layer 290 or the second IL 240 or the work function layers 700, 900 may be separated from the gate spacer 41 by the low-k dielectric spacer layer 42. For example, the second IL 240, the second work function layer 700, the work function tuning layer 900, the optional glue layer, or a combination thereof, can be present between the metal layer 290 and the gate spacer 41 with the low-k dielectric spacer layer 42 therebetween. For example, the second IL 240 may be in direct contact with the low-k dielectric spacer layer 42. In another example, the second work function layer 700 may be in direct contact with the low-k dielectric spacer layer 42. In yet another example, the work function tuning layer 900 may be in direct contact with the low-k dielectric spacer layer 42. In some embodiments, a first portion of the conductive layer 290 may be separated from the gate spacer 41 by the reduced high-k dielectric layer 600S while a second portion of the conductive layer 290 may be separated from the gate spacer 41 by the low-k dielectric spacer layer 42. In some embodiments, the second portion has area that exceeds that of the first portion.

FIGS. 15E and 15F depict embodiments in which the hard mask structures 28 are not present due to being removed in an operation prior to formation of the conductive layer 290. In such embodiments, the conductive layer 290 and optionally the second IL 240 and/or the work function layers 700, 900 may fill space in which the hard mask structures 28 were originally positioned. In some embodiments, to physically and electrically isolate the portion of the gate structure 200 formed where the hard mask structures 28 were located from the neighboring source/drains 82, the inner spacers 74HM described with reference to FIGS. 6A-7B may be positioned between the gate structure 200 and the source/drains 82, as depicted in phantom in FIGS. 15E and 15F.

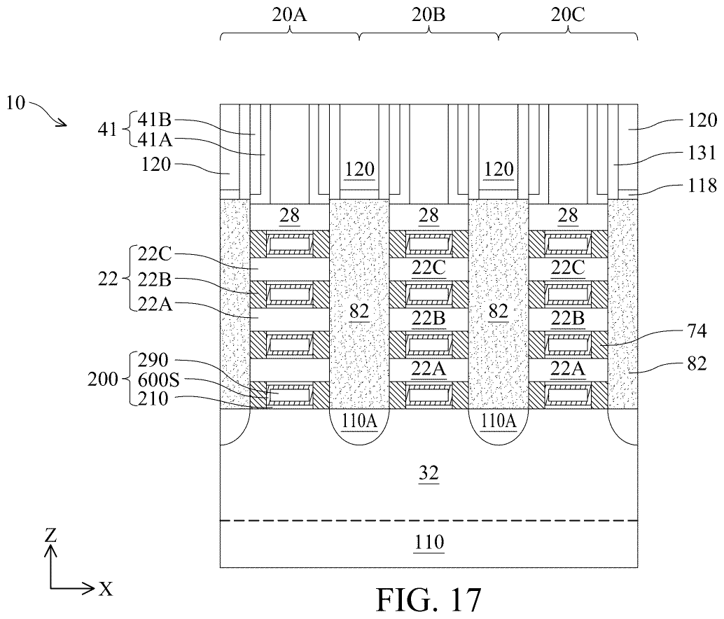

In FIG. 17, following formation of the gate structures 200, source/drain openings may be formed in the ILD 130 and source/drain contacts 120 may be formed in the source/drain openings. Silicide regions 118 and the source/drain contacts 120 are formed on source/drains 82, which can be the source/drain 82P, the source/drain 82N, or a combination thereof.

In some embodiments, the silicide layers 118 are formed prior to formation of the source/drain contacts 120. For example, an N-type or P-type metal layer may be formed as a conformal thin layer over exposed portions of the source/drain regions 82. The metal layer may be or include one or more of Ni, Co, Mn, W, Fe, Rh, Pd, Ru, Pt, Ir, Os or the like. In some embodiments, the metal layer is or includes one or more of Ti, Cr, Ta, Mo, Zr, Hf, Sc, Ys, Ho, Tb, Gd, Lu, Dy, Er, Yb or another suitable material. Following formation of the metal layer, the silicide layers 118 may be formed by annealing the device 10. Following the anneal, the silicide layers 118 may be or include one or more of NiSi, CoSi, MnSi, Wsi, FeSi, RhSi, PdSi, RuSi, PtSi, IrSi, OsSi, TiSi, CrSi, TaSi, MoSi, ZrSi, HfSi, ScSi, Ysi, HoSi, TbSl, GdSi, LuSi, DySi, ErSi, YbSi or the like. Silicide of the silicide layers 118 may diffuse into regions below the ESL 131. Thickness of the silicide layers 118 may be in a range of about 1 nm to about 10 nm. Below about 1 nm, contact resistance may be too high. Above about 10 nm, the silicide layers 118 may short with the channels 22C.

Following formation of the silicide layers 118, the source/drain contacts 120 are formed by filling the openings over the source/drain regions 82 with, for example, a liner layer and a fill layer. In some embodiments, the source/drain contacts 120 are formed by depositing a material that is or includes a conductive material such as Co, W, Ru, combinations thereof, or the like. In some embodiments, the source/drain contacts 120 are or include a Co-, W- or Ru-based compound or alloy including one or more elements, such as Zr, Sn, Ag, Cu, Au, Al, Ca, Be, Mg, Rh, Na, Ir, W, Mo, Zn, Ni, K, Co, Cd, Ru, In, Os, Si, Ge, Mn, combinations thereof, or the like. The source/drain contacts 120 land on the silicide layer 118 and are in contact with the ESL 131. Description of the device 10 and illustration thereof in many of the figures is given with reference to GAAFETs including vertical stacks of the nanostructures 22. In some embodiments, the silicide layers 118 and the source/drain contacts 120 are formed in and on source/drain regions 82 of FinFET devices.

Additional processing may be performed to finish fabrication of the nanostructure devices 20. For example, gate contacts (or gate vias) may be formed to electrically couple to the gate structures 200. An interconnect structure may then be formed over the source/drain contacts 120 and the gate contacts. The interconnect structure may include a plurality of dielectric layers (including, for example, a second ILD) surrounding metallic features, including conductive traces and conductive vias, which form electrical connection between devices on the substrate 110, such as the nanostructure devices 20A, 20B, 20C, as well as to IC devices external to the IC device 10.

Embodiments may provide advantages. By selectively removing portions of the gate dielectric 600 that are outside the channels 22 and the inner spacers 74 from the gate spacer 41, parasitic capacitance can be reduced without reducing beneficial on current Iₒₙ. The selective removal can be accomplished by use of the mask 520 that includes the sacrificial plugs 500′ and the protective structures 510 selectively grown thereon.

In accordance with at least one embodiment, a method is provided that includes: forming a stack including nanostructure channels, interposers and a hard mask structure by forming a source/drain opening; forming a sacrificial gate structure on the stack; forming a spacer layer adjacent the sacrificial gate structure; releasing the nanostructure channels by removing the interposers; forming a gate dielectric on the nanostructure channels and a side surface of the spacer layer; forming a reduced gate dielectric by removing a portion of the gate dielectric from the side surface of the spacer layer, the portion being laterally adjacent to the nanostructure channels; and forming a gate metal layer on the reduced gate dielectric and exposed portions of the spacer layer.

In accordance with at least one embodiment, a method is provided that includes: forming a stack including alternating nanostructure channels and interposers by forming a source/drain opening that extends through alternating first semiconductor layers and second semiconductor layers; releasing the nanostructure channels by removing the interposers; forming a gate dielectric on the nanostructure channels and on a side surface of a spacer layer that extends from a first level above the nanostructure channels to a second level below the nanostructure channels; forming protective plugs between the nanostructure channels; selectively growing a protective structure on exposed surfaces of the protective plugs; and removing a portion of the gate dielectric exposed by the protective plugs.

In accordance with at least one embodiment, a device is provided that includes a first stack of nanostructures; a second stack of nanostructures immediately adjacent to the first stack of nanostructures along a first direction; a source/drain abutting the first stack of nanostructures along a second direction transverse the first direction; and a gate structure wrapping around the first stack of nanostructures. The gate structure includes a gate dielectric, which includes: a first portion that extends between the nanostructures of the first stack of nanostructures; and a second portion that extends between the nanostructures of the second stack of nanostructures, the first and second portions being discontinuous in a region between the first stack of nanostructures and the second stack of nanostructures along the first direction. The gate structure further includes a gate metal on the gate dielectric, the gate metal extending between the nanostructures of the first stack, between the nanostructures of the second stack and continuously between the first stack of nanostructures and the second stack of nanostructures in the region.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a stack including nanostructure channels, interposers and a hard mask structure by forming a source/drain opening;
forming a sacrificial gate structure on the stack;
forming a spacer layer adjacent the sacrificial gate structure;
releasing the nanostructure channels by removing the interposers;
forming a gate dielectric on the nanostructure channels and a side surface of the spacer layer;
forming a reduced gate dielectric by removing a portion of the gate dielectric from the side surface of the spacer layer, the portion being laterally adjacent to the nanostructure channels; and
forming a gate metal layer on the reduced gate dielectric and exposed portions of the spacer layer.

2. The method of claim 1, further comprising:
prior to the removing a portion of the gate dielectric, selectively growing a protective structure that covers end portions of the gate dielectric on the nanostructure channels.

3. The method of claim 2, wherein the selectively growing a protective structure includes:
forming a plurality of sacrificial interposers between the nanostructure channels; and
growing the protective structure on exposed side surfaces of the plurality of sacrificial interposers.

4. The method of claim 3, wherein the growing the protective structure includes growing the protective structure that has first thickness adjacent the plurality of sacrificial interposers that exceeds second thickness adjacent the end portions of the gate dielectric.

5. The method of claim 3, wherein the removing a portion of the gate dielectric includes removing the portion of the gate dielectric exposed by the sacrificial interposers and the protective structure.

6. The method of claim 1, further comprising:
after the removing a portion of the gate dielectric, removing the hard mask structure.

7. The method of claim 1, further comprising:
after the removing a portion of the gate dielectric, forming a low-k dielectric layer on exposed surfaces of the spacer layer above the hard mask structure.

8. A method, comprising:
forming a stack including alternating nanostructure channels and interposers by forming a source/drain opening that extends through alternating first semiconductor layers and second semiconductor layers;
releasing the nanostructure channels by removing the interposers;
forming a gate dielectric on the nanostructure channels and on a side surface of a spacer layer that extends from a first level above the nanostructure channels to a second level below the nanostructure channels;
forming protective plugs between the nanostructure channels;
selectively growing a protective structure on exposed surfaces of the protective plugs; and
removing a portion of the gate dielectric exposed by the protective plugs.

9. The method of claim 8, wherein the forming a stack includes:
forming a hard mask structure over an uppermost interposer of the interposers during the forming a source/drain opening.

10. The method of claim 9, wherein the forming protective plugs includes forming one of the protective plugs between the uppermost interposer and the hard mask structure.

11. The method of claim 8, wherein the selectively growing a protective structure includes growing tungsten on the protective plugs that include TiN or Si.

12. The method of claim 8, wherein the selectively growing a protective structure includes growing TiN on the protective plugs that include TiN or Al₂O₃.

13. The method of claim 8, wherein the selectively growing a protective structure includes growing silicon, SiGe or tungsten on the protective plugs that include silicon.

14. The method of claim 8, further comprising, after the removing a portion of the gate dielectric:
forming a metal gate layer on the nanostructure channels, the metal gate layer having first thickness in a space vertically between the nanostructure channels and a second thickness outside the space, the second thickness exceeding the first thickness.

15. A device, comprising:
a first stack of nanostructures;
a second stack of nanostructures immediately adjacent to the first stack of nanostructures along a first direction;
a source/drain abutting the first stack of nanostructures along a second direction transverse the first direction; and
a gate structure wrapping around the first stack of nanostructures, the gate structure including:
a gate dielectric including:
a first portion that extends between the nanostructures of the first stack of nanostructures; and
a second portion that extends between the nanostructures of the second stack of nanostructures, the first and second portions being discontinuous in a region between the first stack of nanostructures and the second stack of nanostructures along the first direction; and
a gate metal on the gate dielectric, the gate metal extending between the nanostructures of the first stack, between the nanostructures of the second stack and continuously between the first stack of nanostructures and the second stack of nanostructures in the region.

16. The device of claim 15, further comprising:
a spacer layer that is adjacent the gate dielectric and the gate metal along the second direction.

17. The device of claim 16, wherein the gate metal is in direct contact with the spacer layer in the region and is isolated from the spacer layer between the nanostructures of the first stack and between the nanostructures of the second stack.

18. The device of claim 15, further comprising:
a hard mask structure positioned above an uppermost nanostructure of the first stack of nanostructures;
wherein the gate dielectric wraps partially around the hard mask structure.

19. The device of claim 15, wherein the first portion of the gate dielectric includes an exterior portion that extends beyond side surfaces of the nanostructures of the first stack of nanostructures along the first direction.

20. The device of claim 19, wherein the exterior portion of the gate dielectric has first thickness adjacent a space between two nanostructures of the first stack of nanostructures and second thickness adjacent ends of the two nanostructures, the first thickness exceeding the second thickness.
